(19) United States
(12) Patent Application Publication
(10) Pub. No.: US 2026/0290404 A1
(43) Pub. Date: Sep. 24, 2026

(54) SEMICONDUCTOR MEMORY DEVICE

(71) Applicant: Kioxia Corporation, Tokyo (JP)

(72) Inventor: Takuya NISHIKAWA, Yokkaichi Mie (JP)

(73) Assignee: Kioxia Corporation, Tokyo (JP)

(21) Appl. No.: 19/280,197

(22) Filed: Jul. 25, 2025

(30) Foreign Application Priority Data
Mar. 18, 2025 (JP) 2025-043827

(51) Int. Cl. G11C 5/06; G11C 16/04; H10B 43/10; H10B 43/27; H10B 43/35

(52) U.S. Cl. CPC G11C 5/063; G11C 16/0483; H10B 43/10; H10B 43/27; H10B 43/35

(57) ABSTRACT

According to one embodiment, a semiconductor memory device includes: a plurality of word lines; a first interconnect and a source line provided on one side relative to the plurality of word lines; and a memory pillar, wherein the source line includes a first source portion included on the one side relative to the first interconnect and a second source portion so as to intersect the first interconnect on the other side relative to the first source portion, and the memory pillar includes a first semiconductor portion so as to cover a side surface of a core member and a surface of the core member on the one side, and a second semiconductor portion that is in contact with the second source portion so as to cover a side surface of the second source portion.

### CROSS-REFERENCE TO RELATED APPLICATIONS

This application is based upon and claims the benefit of priority from Japanese Patent Application No. 2025-043827, filed Mar. 18, 2025, the entire contents of which are incorporated herein by reference.

### FIELD

Embodiments described herein relate generally to a semiconductor memory device.

### BACKGROUND

As a semiconductor memory device that can store data in a nonvolatile manner, a NAND flash memory is known. The NAND flash memory uses a three-dimensional memory structure for high integration and large capacity.

### BRIEF DESCRIPTION OF THE DRAWINGS

FIG. 1 is a block diagram showing an example of the arrangement of a memory system including a semiconductor memory device according to an embodiment.

FIG. 2 is a circuit diagram showing an example of the circuit arrangement of the memory cell array of the semiconductor memory device according to the embodiment.

FIG. 3 is a plan view showing an example of the planar layout of the semiconductor memory device according to the embodiment.

FIG. 4 is a plan view showing an example of the planar layout of the memory cell array of the semiconductor memory device according to the embodiment.

FIG. 5 is a sectional view taken along line V-V of FIG. 4, showing an example of the sectional structure of the memory cell array of the semiconductor memory device according to the embodiment.

FIG. 6 is a sectional view taken along line VI-VI of FIG. 5, showing an example of the sectional structure of the memory cell array of the semiconductor memory device according to the embodiment.

FIG. 7 is a sectional view showing an example of the sectional structure of the memory cell array of the semiconductor memory device according to the embodiment.

FIG. 8 is a sectional view showing an example of the sectional structure of the semiconductor memory device according to the embodiment.

FIG. 9 is a sectional view showing an example of the sectional structure of a connection pad of the semiconductor memory device according to the embodiment.

FIG. 10 is a sectional view for explaining an example of a method of manufacturing the semiconductor memory device according to the embodiment.

FIG. 11 is a sectional view for explaining an example of the method of manufacturing the semiconductor memory device according to the embodiment.

FIG. 12 is a sectional view for explaining an example of the method of manufacturing the semiconductor memory device according to the embodiment.

FIG. 13 is a sectional view for explaining an example of the method of manufacturing the semiconductor memory device according to the embodiment.

FIG. 14 is a sectional view for explaining an example of the method of manufacturing the semiconductor memory device according to the embodiment.

FIG. 15 is a sectional view for explaining an example of the method of manufacturing the semiconductor memory device according to the embodiment.

FIG. 16 is a sectional view for explaining an example of the method of manufacturing the semiconductor memory device according to the embodiment.

FIG. 17 is a sectional view for explaining an example of the method of manufacturing the semiconductor memory device according to the embodiment.

FIG. 18 is a sectional view for explaining an example of the method of manufacturing the semiconductor memory device according to the embodiment.

FIG. 19 is a sectional view for explaining an example of the method of manufacturing the semiconductor memory device according to the embodiment.

FIG. 20 is a sectional view for explaining an example of the method of manufacturing the semiconductor memory device according to the embodiment.

FIG. 21 is a sectional view for explaining an example of the method of manufacturing the semiconductor memory device according to the embodiment.

FIG. 22 is a sectional view for explaining an example of the method of manufacturing the semiconductor memory device according to the embodiment.

FIG. 23 is a sectional view for explaining an example of the method of manufacturing the semiconductor memory device according to the embodiment.

FIG. 24 is a sectional view for explaining an example of the method of manufacturing the semiconductor memory device according to the embodiment.

FIG. 25 is a sectional view for explaining an example of the method of manufacturing the semiconductor memory device according to the embodiment.

FIG. 26 is a sectional view for explaining an example of the method of manufacturing the semiconductor memory device according to the embodiment.

FIG. 27 is a circuit diagram showing an example of the circuit arrangement of the memory cell array of the semiconductor memory device according to the first modification.

FIG. 28 is a sectional view showing an example of the sectional structure of the memory cell array of the semiconductor memory device according to the first modification.

FIG. 29 is a sectional view showing an example of the sectional structure of the memory cell array of the semiconductor memory device according to the second modification.

FIG. 30 is a sectional view showing an example of the sectional structure of the memory cell array of the semiconductor memory device according to the third modification.

FIG. 31 is a circuit diagram showing an example of the circuit arrangement of the memory cell array of the semiconductor memory device according to the fourth modification.

FIG. 32 is a sectional view showing an example of the sectional structure of the memory cell array of the semiconductor memory device according to the fourth modification.

FIG. 33 is a sectional view showing an example of the sectional structure of the memory cell array of the semiconductor memory device according to another example.

FIG. 34 is a circuit diagram showing an example of the circuit arrangement of the memory cell array of the semiconductor memory device according to still another example.

FIG. 35 is a sectional view showing an example of the sectional structure of the memory cell array of the semiconductor memory device according to still another example.

### DETAILED DESCRIPTION

In general, according to one embodiment, a semiconductor memory device includes: a plurality of word lines provided separately from each other in a first direction intersecting a surface of a substrate; a first interconnect provided separately from the plurality of word lines in the first direction on one side in the first direction relative to the plurality of word lines; a source line provided separately from the plurality of word lines and the first interconnect on the one side in the first direction relative to the plurality of word lines; and a memory pillar provided to extend in the first direction so as to intersect the plurality of word lines and the first interconnect and having one end coupled to the source line, wherein the source line includes a first source portion included on the one side in the first direction relative to the first interconnect and a second source portion coupled to the first source portion and extending in the first direction so as to intersect the first interconnect in correspondence with the memory pillar on the other side in the first direction relative to the first source portion, and the memory pillar includes a core member extending from a position on the other side in the first direction relative to the plurality of word lines to a position on the other side in the first direction relative to the second source portion, a semiconductor film including a first semiconductor portion provided so as to cover a side surface of the core member and a surface of the core member on the one side in the first direction and a second semiconductor portion that is coupled to the first semiconductor portion and in contact with the second source portion so as to cover a side surface of the second source portion on the one side in the first direction relative to the plurality of word lines, and a stacked film covering a side surface of the first semiconductor portion.

Each embodiment will be described below with reference to the accompanying drawings. The dimensions and ratios of each drawing are not always the same as the actual ones. In the following description, the same reference numerals are assigned to constituent elements having almost the same functions and configurations. In a case where elements having similar arrangements are particularly discriminated from each other, different letters or numbers are sometimes added to the ends of the same reference numerals.

### 1 Embodiment

A semiconductor memory device according to the embodiment will be described below.

### 1.1 Arrangement

The arrangement of a semiconductor memory device according to the embodiment will be described.

### 1.1.1 Memory System

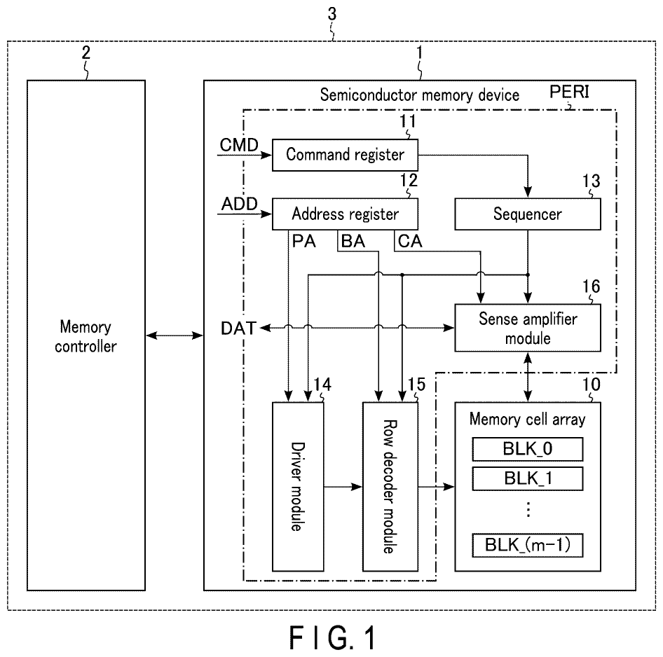

An example of the arrangement of a memory system will be described with reference to FIG. 1. FIG. 1 is a block diagram showing an example of the arrangement of the memory system including the semiconductor memory device according to the embodiment.

A memory system 3 is, for example, an SSD (solid state drive) or SD™ card. The memory system 3 is coupled to an external host device (not shown). The memory system 3 stores data from the host device. The memory system 3 outputs data to the host device.

The memory system 3 includes a semiconductor memory device 1 and a memory controller 2.

The semiconductor memory device 1 is, for example, a NAND flash memory. The semiconductor memory device 1 stores data in a nonvolatile manner. The following is a case where the semiconductor memory device 1 is a NAND flash memory.

The memory controller 2 is composed of, for example, an integrated circuit such as an SoC (system-on-a-chip). For example, the memory controller 2 writes data to the semiconductor memory device 1 based on a request from the host device. In addition, the memory controller 2 reads data from the semiconductor memory device 1 based on a request from the host device. The memory controller 2 transmits the data read from the semiconductor memory device 1 to the host device.

The semiconductor memory device 1 and the memory controller 2 communicate with each other in compliance with, for example, an SDR (single data rate) interface, toggle DDR (double data rate) interface, or ONFI (Open NAND flash interface).

### 1.1.2 Semiconductor Memory Device

The internal arrangement of the semiconductor memory device 1 will be further described with reference to FIG. 1. The semiconductor memory device 1 includes, for example, a memory cell array 10 and a peripheral circuit PERI. The peripheral circuit PERI includes, for example, a command register 11, an address register 12, a sequencer 13, a driver module 14, a row decoder module 15, and a sense amplifier module 16.

The memory cell array 10 includes a plurality of blocks BLK0 to BLK(m−1) (where m is an integer equal to or more than 2). A block BLK is a set of a plurality of memory cells that can store data in a nonvolatile manner. The block BLK is used as a unit of data erasure. The memory cell array 10 is provided with a plurality of bit lines and a plurality of word lines. One memory cell is associated with one bit line and one word line.

The command register 11 holds a command CMD received by the semiconductor memory device 1 from the memory controller 2. The command CMD includes, for example, instructions for making the sequencer 13 execute a read operation, a write operation, and an erase operation.

The address register 12 holds address information ADD received by the semiconductor memory device 1 from the memory controller 2. The information ADD includes, for example, a page address PA, a block address BA, and a column address CA. The page address PA, the block address BA, and the column address CA are respectively used to select, for example, a word line, the block BLK, and a bit line.

The sequencer 13 controls the overall operation of the semiconductor memory device 1. The sequencer 13 executes a read operation, a write operation, and an erase operation based on the command CMD stored in the command register 11.

The driver module 14 generates voltages used for a read operation, a write operation, and an erase operation. The driver module 14 applies a generated voltage to a signal line corresponding to a selected word line based on the page address PA held in the address register 12.

Based on the block address BA held in the address register 12, the row decoder module 15 selects one corresponding block BLK in the memory cell array 10. The row decoder module 15 then transfers, for example, the voltage applied to a signal line corresponding to the selected word line to the word line selected in the selected block BLK.

In a write operation, the sense amplifier module 16 transfers write data DAT received from the memory controller 2 to the memory cell array 10. The sense amplifier module 16 also executes determination on data stored in a memory cell based on the voltage of a bit line in a read operation. The sense amplifier module 16 transfers the determination result as the read data DAT to the memory controller 2.

### 1.1.3 Circuit Arrangement of Memory Cell Array

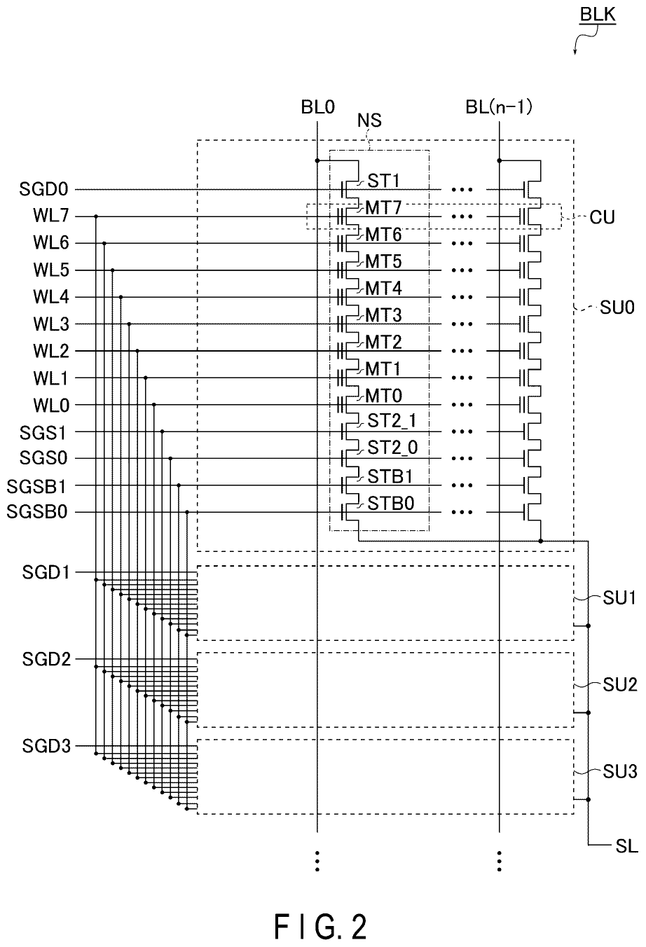

An example of the circuit arrangement of the memory cell array 10 will be described with reference to FIG. 2. FIG. 2 is a circuit diagram showing an example of the circuit arrangement of the memory cell array of the semiconductor memory device according to the embodiment. FIG. 2 shows one block BLK of the plurality of blocks BLK included in the memory cell array 10. In the example shown in FIG. 2, the block BLK includes four string units SU0, SU1, SU2, and SU3. In the following description, when the string units SU0, SU1, SU2, and SU3 are not discriminated from each other, each of the string units SU0, SU1, SU2, and SU3 is also simply referred to as a string unit SU.

Each string unit SU includes a plurality of NAND strings NS respectively associated with bit lines BL0 to BL(n−1) (where n is an integer equal to or more than 2). Each NAND string NS includes, for example, memory cell transistors MT0 to MT7 and selection transistors ST1, ST2_0, ST2_1, STB0, and STB1. In the following description, when the bit lines BL0 to BL(n−1) are not discriminated from each other, each of the bit lines BL0 to BL(n−1) is also simply referred to as a bit line BL. In addition, when the memory cell transistors MT0 to MT7 are not discriminated from each other, each of the memory cell transistors MT0 to MT7 is also simply referred to as a memory cell transistor MT. When the selection transistors ST2_0 and ST2_1 are not discriminated from each other, each of the selection transistors ST2_0 and ST2_1 is also simply referred to as a selection transistor ST2. When the selection transistors STB0 and STB1 are not discriminated from each other, each of the selection transistors STB0 and STB1 is also simply referred to as a selection transistor STB.

Each of the memory cell transistors MT0 to MT7 includes a control gate and a charge storage film. Each of the memory cell transistors MT0 to MT7 holds data in a nonvolatile manner. The selection transistor ST1 is used to select the string unit SU in each type of operation. The selection transistor ST2 is used to select the block BLK in each type of operation. The selection transistor STB is used to select the block BLK, like the selection transistor ST2, in a write operation and a read operation. For example, in an erase operation, the selection transistor STB is used to generate a GIDL (gate induced drain leakage) current. This embodiment exemplifies a case where each NAND string NS includes the eight memory cell transistors MT. However, the number of memory cell transistors MT of each NAND string NS may be, for example, 16, 32, 48, 64, 96, or 128 or an arbitrary number. Although the embodiment exemplifies a case where each NAND string NS includes the one selection transistor ST1, the two selection transistors ST2, and the two selection transistors STB, the numbers of selection transistors ST1, ST2, and STB are arbitrary and each may be one or more.

In each NAND string NS, the memory cell transistors MT0 to MT7 are coupled in series. One terminal of the selection transistor ST1 is coupled to the bit line BL associated with the selection transistor ST1. The other terminal of the selection transistor ST1 is coupled to one terminal of the memory cell transistors MT0 to MT7 coupled in series. The other terminal of each of the memory cell transistors MT0 to MT7 coupled in series is coupled to one terminal of a corresponding one of the selection transistors ST2_0 and ST2_1 coupled in series. The other terminal of each of the selection transistors ST2_0 and ST_1 coupled in series is coupled to one terminal of a corresponding one of the selection transistors STB0 and STB1 coupled in series. The other terminal of each of the selection transistors STB0 and STB1 coupled in series is coupled to a source line SL.

In each block BLK, the control gates of the memory cell transistors MT0 to MT7 are respectively coupled to word lines WL0 to WL7. In the following description, when the word lines WL0 to WL7 are not discriminated from each other, each of the word lines WL0 to WL7 is also simply referred to as a word line WL.

The string units SU0 to SU3 respectively correspond to selection gate lines SGD0 to SGD3. When the selection gate lines SGD0 to SGD3 are not discriminated from each other, each of the selection gate lines SGD0 to SGD3 is also simply referred to as a selection gate line SGD. In each string unit SU, the gate of the selection transistor ST1 is coupled to the selection gate line SGD corresponding to the string unit SU of the selection gate lines SGD0 to SGD3.

In each block BLK, the gates of the plurality of selection transistors ST2_0 are commonly coupled to a selection gate line SGS0. The gates of the plurality of selection transistor ST2_1 are commonly coupled to a selection gate line SGS1. For example, the selection gate lines SGS0 and SGS1 are controlled commonly in potential. However, the present invention is not limited to this arrangement, and the gates of the plurality of selection transistors ST2_0 may be respectively coupled to the plurality of selection gate lines SGS0 differing for each string unit SU. The gates of the plurality of selection transistors ST2_1 may be respectively coupled to the plurality of selection gate lines SGS1 differing for each string unit SU. In the following description, when the selection gate lines SGS0 and SGS1 are not discriminated from each other, each of the selection gate lines SGS0 and SGS1 is also simply referred to as a selection gate line SGS.

In each block BLK, the gates of the plurality of selection transistors STB0 are commonly coupled to a selection gate line SGSB0. The gates of the plurality of selection transistors STB1 are commonly coupled to a selection gate line SGSB1. In addition, for example, the selection gate lines SGSB0 and SGSB1 are controlled commonly in potential. However, the present invention is not limited to this arrangement, and the gates of the plurality of selection transistors STB0 may be respectively coupled to the plurality of selection gate lines SGSB0 differing for each string unit SU. In addition, the gates of the plurality of selection transistors STB1 may be respectively coupled to the plurality of selection gate lines SGSB1 differing for each string unit SU. The selection gate lines SGSB0 and SGSB1 are controlled in potential independently of the selection gate lines SGS0 and SGS1. In the following description, when the selection gate lines SGSB0 and SGSB1 are not discriminated from each other, each of the selection gate lines SGSB0 and SGSB1 is also simply referred to as a selection gate line SGSB.

Different column addresses CA are respectively assigned to the bit lines BL0 to BL(n−1). Each bit line BL is shared by the NAND strings NS assigned with the same column address CA between a plurality of blocks BLK. The word lines WL0 to WL7 are provided for each block BLK. The source line SL is shared between the plurality of blocks BLK.

A set of the plurality of memory cell transistors MT coupled to the common word line WL in the one string unit SU is referred to as, for example, a cell unit CU. The storage capacity of the cell unit CU including a plurality of memory cell transistors MT each storing 1-bit data is defined as, for example, “1-page data”. The cell unit CU can have a storage capacity of 2-page data or more in accordance with the number of bits of data stored in each memory cell transistor MT.

Note that the circuit arrangement of the memory cell array 10 is not limited to the arrangement described above. For example, the number of string units SU included in each block BLK may be an arbitrary number.

### 1.1.4 Structure of Semiconductor Memory Device

An example of the structure of the semiconductor memory device 1 according to the embodiment will be described.

In the following description, the X direction is a direction almost parallel to the semiconductor substrate of the semiconductor memory device 1. The X direction corresponds to the extending direction of the word line WL. The Y direction is a direction almost parallel to the semiconductor substrate and orthogonal to the X direction. The Y direction corresponds to the extending direction of the bit line BL. A Z1 direction and a Z2 direction are directions almost perpendicular to the semiconductor substrate. The Z1 direction corresponds to a direction from the semiconductor substrate of the semiconductor memory device 1 to an electrode pad. The Z2 direction corresponds to a direction from the electrode pad to the semiconductor substrate. Note that when the Z1 direction and the Z2 direction are not discriminated from each other, each of the Z1 direction and the Z2 direction is simply referred to as the Z direction. In the following description, the Z1-direction side with respect to a given constituent element is also referred to as one side in the Z direction (or simply one side), and the Z2-direction side with respect to a given constituent element is also referred as the other side in the Z direction (or simply the other side). In addition, a surface of a given constituent element which is located on the above electrode pad side is referred to as the first surface, and a surface of a given constituent element which is located on the semiconductor substrate side is referred to as the second surface. The above first and second surfaces can be respectively referred to as one side surface in the Z direction and the other side surface in the Z direction.

### 1.1.4.1 Structure of Memory Cell Array

An example of the structure of the memory cell array 10 will be described

### 1.1.4.1.1 Overall Arrangement of Memory Cell Array

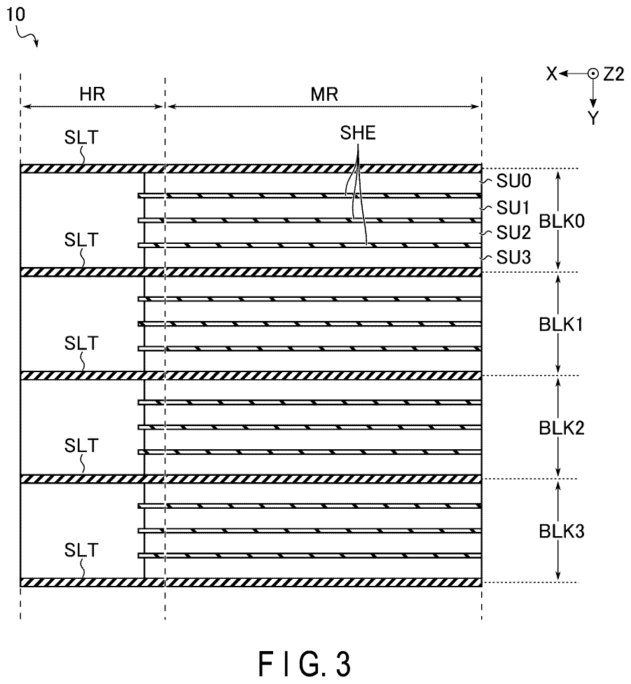

The overall arrangement of the memory cell array 10 will be described with reference to FIG. 3. FIG. 3 is a plan view showing an example of the planar layout of the semiconductor memory device according to the embodiment. FIG. 3 shows regions corresponding to four blocks BLK0 to BLK3.

The memory cell array 10 includes a stacked interconnect structure, members SLT, and members SHE. The stacked interconnect structure includes the selection gate lines SGD, SGS0, SGS1, SGSB0, and SGSB1 and the plurality of word lines WL. The stacked interconnect structure has layers stacked along the Z direction in accordance with the stacking numbers of selection gate lines SGD, SGS0, SGS1, SGSB0, and SGSB1 and word lines WL. In the following description, the selection gate lines SGD, SGS, and SGSB and the plurality of word lines WL are also collectively referred to as stacked interconnects.

For example, a stacked interconnect structure is provided throughout a memory region MR and a hookup region HR in the X direction.

The memory region MR is a region in which data is substantially stored.

The hookup region HR is a region used to couple the stacked interconnects to the peripheral circuit PERI such as the row decoder module 15.

Each member SLT extends in the X direction. Each member SLT crosses the stacked interconnect structure in the X direction throughout the memory region MR and the hookup region HR. Each member SLT has a structure (closed structure) embedded with, for example, an insulator or plate-like conductor. Each member SLT divides stacked interconnects adjacent to each other through the member SLT. The regions delimited by the plurality of members SLT each correspond to one block BLK. In the example shown in FIG. 3, the blocks BLK0, BLK1, BLK2, and BLK3 are arranged in this order.

Each member SHE extends in the X direction. The embodiment exemplifies a case where the three members SHE are provided between the adjacent members SLT. Each member SHE crosses the stacked interconnect structure in the X direction throughout the memory region MR. Each member SHE has, for example, a structure embedded with an insulator. Each member SHE divides the selection gate lines SGD adjacent to each other through the member SHE. The regions delimited by the members SLT and the members SHE each correspond to one string unit SU. In the example shown in FIG. 3, the string units SU0, SU1, SU2, and SU3 are arranged in this order.

In the memory cell array 10, for example, the planar layout shown in FIG. 3 is repeatedly arranged in the Y direction.

The planar layout of the memory cell array 10 is not limited to the layout described above. For example, the number of members SHE arranged between the adjacent members SLT can be designed to be an arbitrary number in accordance with the number of string units SU included in the block BLK.

### 1.1.4.1.2 Structure of Memory Cell Array in Memory Region

The structure of the memory cell array 10 in the memory region MR will be described.

### 1.1.4.1.2.1 Planar Structure

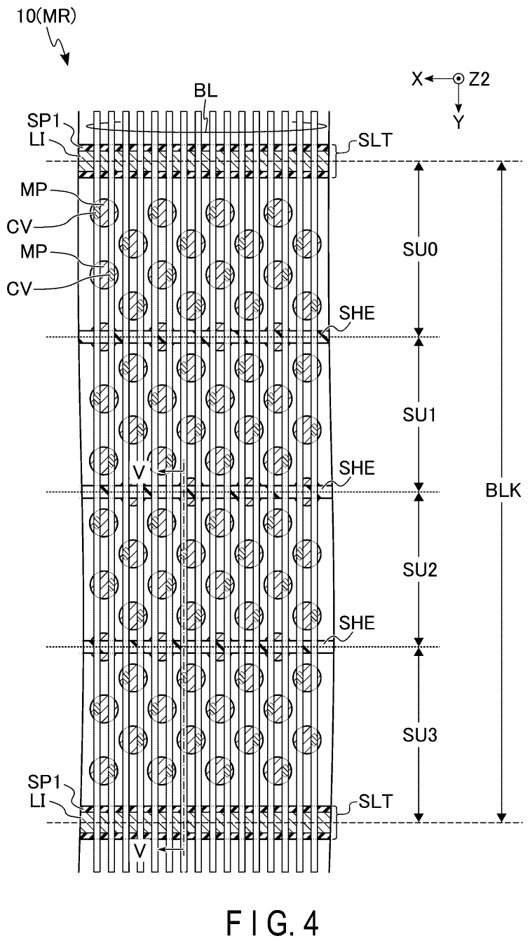

The planar structure of the memory cell array 10 in the memory region MR will be described with reference to FIG. 4. FIG. 4 is a plan view showing an example of the planar layout of the memory cell array of the semiconductor memory device according to the embodiment.

In the memory region MR, the memory cell array 10 includes a plurality of memory pillars MP, a plurality of contacts CV, and a plurality of bit lines BL. Each member SLT includes a core portion LI and a spacer SP1.

Each memory pillar MP functions as, for example, one NAND string NS. The plurality of memory pillars MP are arranged in a 19-row staggered pattern in the region between the two adjacent members SLT. For example, one member SHE is stacked on each of the memory pillars MP respectively located on the fifth, 10th, and 15th columns counted from the string unit SU0 of the string units SU0 to SU3.

Each of the plurality of bit lines BL extends in the Y direction. The plurality of bit lines BL are arranged side by side in the X direction. Each bit line BL is arranged to overlap at least one memory pillar MP for each string unit SU. In the example shown in FIG. 4, each bit line BL is arranged to overlap the two memory pillars MP for each string unit SU. One of the plurality of bit lines BL which overlaps the memory pillar MP is coupled to the memory pillar MP through the contact CV. For example, no contact is provided between the memory pillar MP that overlaps the member SHE and the bit line BL. That is, the memory pillar MP overlapping the member SHE is not electrically coupled to the bit line BL.

A core portion LI is a conductor provided to extend in the X direction. A spacer SP1 is an insulator provided on a side surface of the core portion LI. The core portion LI is sandwiched between the spacers SP1. The core portion LI is electrically separated from the stacked interconnect adjacent to the core portion LI in the Y direction by the spacer SP1. This electrically insulates the core portion LI from the stacked interconnect adjacent to the core portion LI in the Y direction.

### 1.1.4.1.2.2 Sectional Structure

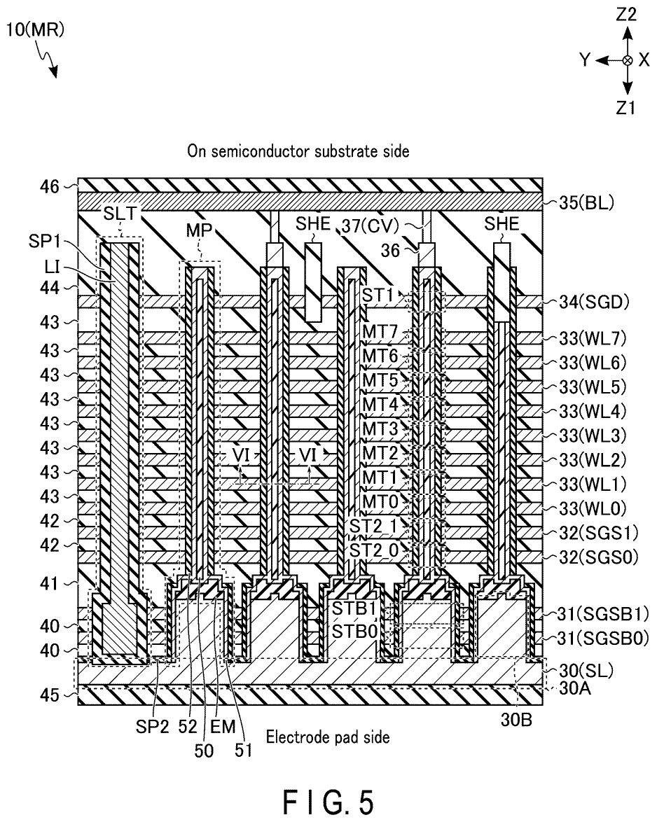

The sectional structure of the memory cell array 10 in the memory region MR will be described with reference to FIG. 5. FIG. 5 is a sectional view showing an example of the sectional structure of the memory cell array of the semiconductor memory device according to the embodiment. The sectional view of FIG. 5 is a sectional view taken along line V-V in FIG. 4.

The memory cell array 10 further includes conductor layers 30, 34, and 35, two conductor layers 31, two conductor layers 32, pluralities of conductor layers 33, 36, and 37, two insulator layers 40, two insulator layers 42, insulator layers 41, 44, 45, and 46, a plurality of insulator layers 43, and a spacer SP2. FIG. 5 shows the five memory pillars MP of the plurality of memory pillars MP. The memory cell array 10 is provided between the electrode pad and the semiconductor substrate of the semiconductor memory device 1 in the Z direction.

The conductor layer 30 includes a conductor portion 30A and a plurality of conductor portions 30B which are coupled to each other. The conductor portion 30A is provided, for example, in a plate form expanding along an XY plane. The plurality of conductor portions 30B are provided, for example, on the other side relative to the conductor portion 30A in accordance with the plurality of memory pillars MP. The structure of the plurality of conductor portions 30B will be described in detail later. The conductor layer 30 is used as the source line SL. The conductor layer 30 is made of, for example, a metal material. The metal material includes, for example, tungsten (W) or titanium nitride (TiN).

The two insulator layers 40 and the two conductor layers 31 are stacked on the other side of the conductor portion 30A in the order of the insulator layer 40, the conductor layer 31, the insulator layer 40, and the conductor layer 31 toward the Z2 direction. Each conductor layer 31 is formed in a plate form expanding along an XY plane. The conductor layer 31 of the two conductor layers 31 which is located on one side is used as the selection gate line SGSB0. The conductor layer 31 of the two conductor layers 31 which is located on the other side is used as the selection gate line SGSB1. The conductor layer 31 contains, for example, tungsten or molybdenum (Mo).

The insulator layer 41 is stacked on the second surface of the conductor layer 31 of the two conductor layers 31 which is located on the other side. The two conductor layers 32 and the two insulator layers 42 are stacked on the second surface of the insulator layer 41 in the order of the conductor layer 32, the insulator layer 42, the conductor layer 32, and the insulator layer 42 toward the Z2 direction. The conductor layer 32 is formed in a plate form expanding along an XY plane. The conductor layer 32 of the two conductor layers 32 which is located on one side is used as the selection gate line SGS0. The conductor layer 32 of the two conductor layers 32 which is located on the other side is used as the selection gate line SGS1. The conductor layer 32 contains, for example, tungsten or molybdenum.

The eight conductor layers 33 and the eight insulator layers 43 are stacked on the second surface of the insulator layer 42 of the two insulator layers 42 which is located on the other side in the order of the conductor layer 33, the insulator layer 43, . . . , the conductor layer 33, and the insulator layer 43 toward the Z2 direction. The conductor layer 33 is formed in a plate form expanding along an XY plane. The eight conductor layers 33 are sequentially used as the word lines WL0 to WL7 along the Z2 direction. The conductor layer 33 contains, for example, tungsten or molybdenum.

The conductor layer 34 is stacked on the second surface of the insulator layer 43 of the eight insulator layers 43 which is located on the other side in the Z direction. The conductor layer 34 is formed in a plate form expanding along an XY plane. The conductor layer 34 is used as the selection gate line SGD. The conductor layer 34 contains, for example, tungsten or molybdenum.

The conductor layer 34 is electrically insulated by, for example, the plurality of members SHE for each string unit SU.

The insulator layer 44 is stacked on the second surface of the conductor layer 34. The plurality of conductor layers 35 are stacked on the second surface of the insulator layer 44. Each conductor layer 35 is provided to extend along the Y direction. For this reason, FIG. 5 shows only the one conductor layer 35. Each conductor layer 35 functions as the bit line BL. Each conductor layer 35 is electrically coupled to the plurality of memory pillars MP through the plurality of conductor layers 36 and 37.

The stacked structure including the conductor layers 30 to 37 described above is provided so as to be surrounded by an insulator. FIG. 5 shows the insulator layer 45 in contact with the first surface of the semiconductor substrate 30 and the insulator layer 46 in contact with the second surface of the conductor layer 35. Although not shown in FIG. 5, as described later, the conductor layer 30 is coupled to the peripheral circuit PERI through, for example, a conductor layer located on one side relative to the conductor layer 30. Although not shown in FIG. 5, as described later, the conductor layer 35 is coupled to the peripheral circuit PERI through a conductor layer located on the other side relative to the conductor layer 35.

A conductor portion 30B is provided for the conductor layer 30 so as to, for example, extend through the two conductor layers 31. The conductor portion 30B is provided, for example, in a pillar shape extending along the Z direction. The conductor portion 30B has, for example, a tapered shape increasing in width in the X and Y directions toward the Z2 direction.

The plurality of memory pillars MP are provided to extend along the Z direction on one side relative to the conductor layer 35. The plurality of memory pillars MP extend through, for example, the conductor layers 31 to 34.

Each of the plurality of memory pillars MP includes a core member 50, a semiconductor film 51, a stacked film 52, an insulator portion EM, and the spacer SP2.

In each memory pillar MP, the insulator portion EM is provided on the second surface of the conductor portion 30B. The insulator portion EM is included, for example, on one side relative to the two conductor layers 32. The insulator portion EM contains, for example, silicon oxide.

The core member 50 is provided to extend along the Z direction on the other side of the insulator portion EM. The core member 50 contains an insulator such as silicon oxide.

The semiconductor film 51 covers the surroundings of the core member 50 on the other side of the insulator portion EM. The semiconductor film 51 covers the side surfaces of the insulator portion EM and the side surfaces of the conductor portion 30B. The semiconductor film 51 is also in contact with the second surface of the conductor portion 30A. The semiconductor film 51 contains, for example, silicon. With the above arrangement, the semiconductor film 51 is joined to the conductor portion 30B by Schottky junction. The arrangement of the semiconductor film 51 will be described in detail later.

The stacked film 52 covers the side surfaces of the semiconductor film 51 on the other side relative to the insulator portion EM. The first surface of the stacked film 52 is located on one side relative to the two conductor layers 32. The arrangement of the stacked film 52 will be described later.

On one side relative to the stacked film 52, a portion of the spacer SP2 covers portions of the side surfaces of the semiconductor film 51 which are included in the same height as at least the two conductor layers 31. For example, the other portion of the spacer SP2 is also provided between the insulator layer 40 and the conductor portion 30A in the Z direction. The spacer SP2 contains, for example, silicon oxide. That is, the spacer SP2 is formed of an insulating film as a single layer and different in film structure from the stacked film 52. The portions of the stacked film 52 and the spacer SP2 which cover the side surfaces of the semiconductor film 51 can be regarded as components included in the memory pillar MP corresponding to the semiconductor film 51.

The conductor layer 36 is provided on the second surface of the semiconductor film 51. The conductor layer 36 functions as, for example, a columnar contact. The conductor layer 37 is provided on the second surface of the conductor layer 36. The conductor layer 37 functions as, for example, the contact CV.

With the above arrangement, the conductor layers 36 and 37 electrically couple the semiconductor film 51 to the conductor layer 35. The one conductor layer 36 and the one conductor layer 37 are coupled to the one conductor layer 35 in the space delimited by the members SLT and SHE.

The member SLT divides the conductor layers 31 to 34. The core portion LI in the member SLT is provided along the member SLT. The second surface of the core portion LI is located between the conductor layer 34 (the selection gate line SGD) and the conductor layer 35. The spacer SP1 covers the side surfaces and the first surface of the core portion LI. This makes the spacer SP1 isolate and insulate between each of the conductor layers 31 to 34 and the core portion LI. In addition, the spacer SP1 isolates and insulates between the core portion LI and the conductor layer 30. The core portion LI is formed of, for example, a semiconductor member such as silicon or a metal material.

The member SLT is configured to have a stepped portion on one side relative to the two conductor layers 32. The stepped portion is located, for example, between the two conductor layers 31 and the two conductor layers 32. A portion of the member SLT which is located on one side relative to the stepped portion is provided to, for example, increase in width in the X direction and the Y direction as compared with the portion on the other side. Like the member SLT, the core portion LI has a stepped portion. For example, a portion of the core portion LI which is located on one side relative to the two conductor layers 32 is also provided to increase in width in the X direction and the Y direction as compared with the portion on the other side relative to the above portion in accordance with the shape of the member SLT.

Although not shown in FIG. 5, the core portion LI may contain a barrier metal. That is, the core portion LI may have, for example, a structure having a barrier metal covering the side surfaces and the first surface of a metal material including tungsten.

A portion where the conductor layer 31, each of the plurality of memory pillars MP, and the conductor portion 30B corresponding to the memory pillar MP intersect each other functions as a selection transistor STB. A portion where the conductor layer 32 intersects each of the memory pillars MP functions as the selection transistor ST2. A portion where each of the plurality of memory pillars MP intersects each conductor layer 33 functions as the memory cell transistor MT. A portion where each of the plurality of memory pillars MP intersects each conductor layer 34 functions as the selection transistor ST1.

### 1.1.4.1.2.3 Sectional Structure of Memory Pillar

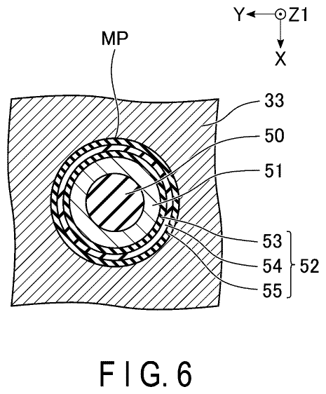

The sectional structure of the memory pillar MP will be described with reference to FIG. 6. FIG. 6 is a sectional view taken along line VI-VI of FIG. 5, showing an example of the sectional structure of the memory cell array of the semiconductor memory device according to the embodiment.

The stacked film 52 includes a tunnel insulating film 53, a charge storage film 54, and a block insulating film 55.

The tunnel insulating film 53 covers the side surface of the semiconductor film 51 on the other side relative to the first surface of the conductor layer 32 of at least the two conductor layers 32 which is located on one side. The charge storage film 54 covers the side surface of the tunnel insulating film 53. The block insulating film 55 covers the side surface of the charge storage film 54.

The tunnel insulating film 53 and the block insulating film 55 contain, for example, silicon oxide. The charge storage film 54 contains, for example, silicon nitride. The charge storage film 54 is a film that can store charge.

### 1.1.4.1.2.4 Structures of Memory Pillar MP and Member SLT

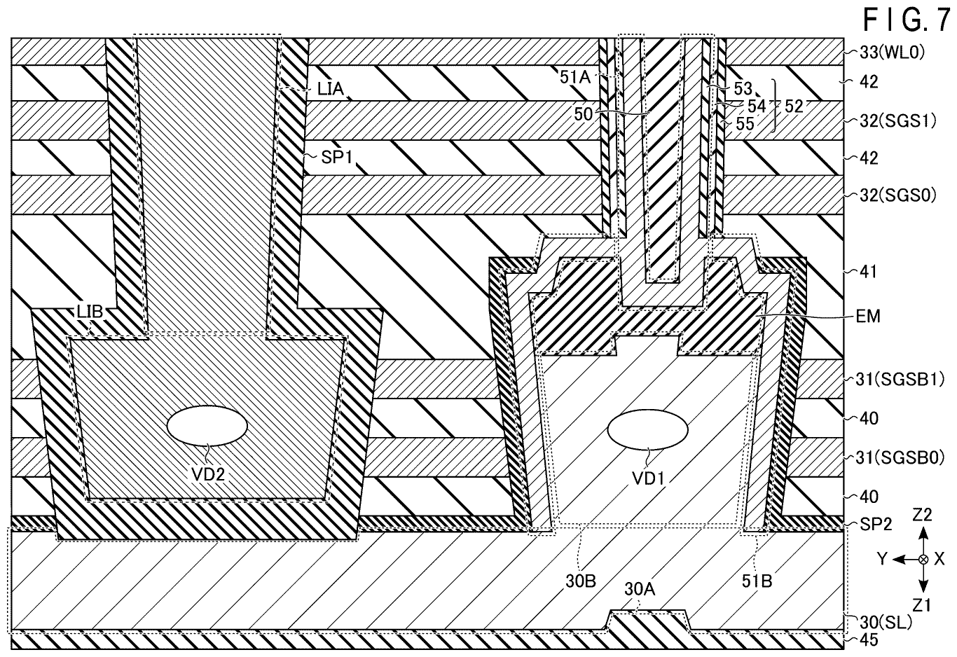

The portion of the memory pillar MP which is located on one side, the portion of the member SLT which is located on one side, and structures around them will be described with reference to FIG. 7. FIG. 7 is a sectional view showing an example of the sectional structure of the memory cell array of the semiconductor memory device according to the embodiment.

The conductor portion 30B is, for example, provided to increase in width in the X direction and the Y direction along the Z2 direction.

The conductor portion 30B includes a void VD1 originating from, for example, the embedding of the conductor layer 30 in a manufacturing process (to be described later). However, the present invention is not limited to this. The conductor portion 30B may not include the void VD1. The surface of the conductor portion 30A which is located on one side has a surface portion receding to the other side at a portion corresponding to the memory pillar MP due to, for example, the embedding of the conductor layer 30.

The conductor portion 30B which is located on the other side relative to the conductor portion 30A has a portion protruding to the other side due to the formation of the insulator portion EM in a manufacturing process described later. However, the present invention is not limited to this, and the second surface of the conductor portion 30B may be flat.

The insulator portion EM has, for example, on one side, a portion receding to the other side in correspondence with the above portion of the conductor portion 30B which is located on the other side. If the second surface of the conductor portion 30B is flat, the first surface of the insulator portion EM is flat like the second surface of the conductor portion 30B.

The second surface of the insulator portion EM which is located on the other side has, for example, a portion receding to one side in correspondence with the core member 50. In addition, the receding portion of the insulator portion EM which is located on the other side is, for example, located on one side relative to the portion of the peripheral region of the above portion which surrounds the portion receding to one side in the X direction and the Y direction.

As described above, the semiconductor film 51 includes a portion covering the surroundings of the core member 50 and a portion covering the side surfaces of the insulator portion EM and the conductor portion 30B. In the following description, the portion covering the surroundings of the core member 50 is also referred to as a semiconductor portion 51A. The portion covering the side surfaces of the insulator portion EM and the conductor portion 30B is also referred to as a semiconductor portion 51B. The semiconductor portion 51A is, for example, in contact with the portion of the insulator portion EM which is receding to one side in correspondence with the core member 50. The semiconductor portion 51B covers the surroundings of the insulator portion EM and the conductor portion 30B except for a portion where the semiconductor portion 51A is in contact with the insulator portion EM. In addition, the semiconductor portion 51B is in contact with the portion of the semiconductor portion 51A which is located on one side.

The portion of the memory pillar MP which includes the semiconductor portion 51B is larger in a sectional area in an XY plane than the portion of the memory pillar MP which includes the stacked film 52 and is located on one side. Assume that the sectional area of the portion of the memory pillar MP which includes the semiconductor portion 51B is, for example, the sectional area of the portion including a structure located more inside than the semiconductor portion 51B. For example, the sectional area of the memory pillar MP in the same layer as each conductor layer 31 is larger than each sectional area of the memory pillar MP in the same layer as the conductor layer 33 of the plurality of conductor layers 33 which is located on one side and each of the two conductor layers 32. In addition, for example, the portion of the memory pillar MP including the insulator portion EM is larger in a sectional area in an XY plane than the portion of the memory pillar MP in the same layer as the conductor layer 33 of the plurality of conductor layers 33 which is located on one side and each of the two conductor layers 32.

In an XY plane, the conductor portion 30B is larger in a sectional area than the portion of the memory pillar MP which includes the stacked film 52 and is located on one side. For example, the sectional area of the conductor portion 30B in an XY plane is larger than each sectional area of the memory pillar MP in the same layer as each of the two conductor layers 32 and the conductor layer 33 of the plurality of conductor layers 33 which is located on one side.

In an XY plane, the central positions of the conductor portion 30B and the insulator portion EM and the central position of the core member 50 may be the same or different. Accordingly, in an XY plane, the central portion of the semiconductor portion 51A and the central position of the semiconductor portion 51B may be the same or different. In the example shown in FIG. 7, the central positions of the conductor portion 30B and the insulator portion EM are different from the central position of the core member 50.

As described above, in the member SLT, the core portion LI has a stepped portion on one side relative to the two conductor layers 32. In the following description, the portion of the core portion LI which is located on the other side relative to the position of the stepped portion is also referred to as a core portion LIA. In addition, the portion of the core portion LI which is located on one side relative to the position is also referred to as a core portion LIB. The core portion LIB includes, for example, a void VD2. However, the present invention is not limited to this, and the core portion LIB may not include the void VD2.

The core portion LIB is provided so as to, for example, increase in width in the X direction or the Y direction along the Z2 direction.

In an XY plane, the core portion LIB is larger in a sectional area than at least the portion of the core portion LIA which is located on one side. For example, the sectional area of the core portion LIB in an XY plane is larger than each sectional area of the core portion LIA in the same layer as each of the conductor layer 33 of the plurality of conductor layers 33 which is located on one side and each of the two conductor layers 32.

The first surface of the spacer SP1 is located at the same position as the first surface of the spacer SP2 or on one side relative to the first surface of the spacer SP2.

### 1.1.4.2 Overall Sectional Structure of Semiconductor Memory Device

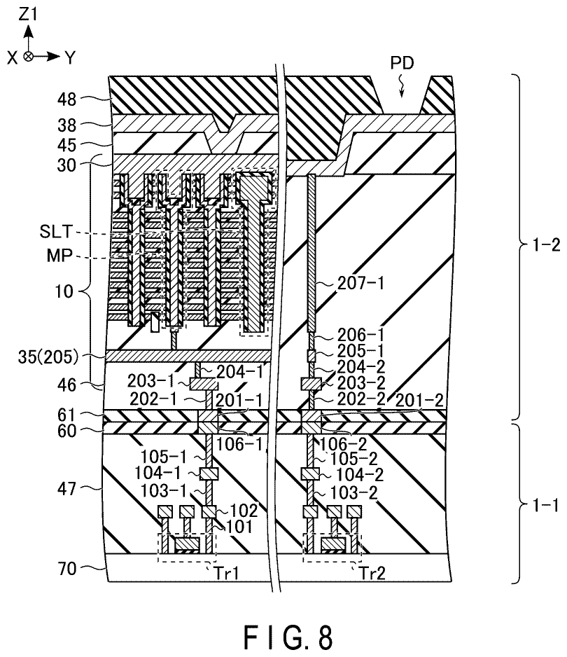

The overall sectional structure of the semiconductor memory device 1 will be described with reference to FIG. 8. FIG. 8 is a sectional view showing an example of the sectional structure of the semiconductor memory device according to the embodiment. FIG. 8 shows the sectional structure of a portion of the semiconductor memory device 1.

The semiconductor memory device 1 has a structure having a circuit chip 1-1 and a memory chip 1-2 bonded to each other.

### 1.1.4.2.1 Circuit Chip

The sectional structure of the circuit chip 1-1 will be described first.

The circuit chip 1-1 includes, for example, a semiconductor substrate 70, a plurality of conductor layers 101, 102, 103, 104, 105, and 106, which constitute a portion of the peripheral circuit PERI and insulator layers 47 and 60. The semiconductor substrate 70 is formed of a p-type semiconductor doped with an impurity.

Each of the plurality of conductor layers 101 to 106 functions as, for example, a columnar contact or interconnect. The plurality of conductor layers 103 include conductor layers 103-1 and 103-2. The plurality of conductor layers 104 include conductor layers 104-1 and 104-2. The plurality of conductor layers 105 include conductor layers 105-1 and 105-2. The plurality of conductor layers 106 include conductor layers 106-1 and 106-2.

The insulator layer 47 is provided on the first surface of the semiconductor substrate 70. The insulator layer 47 contains, for example, silicon oxide. The insulator layer 47 is internally provided with the plurality of conductor layers 101, 102, 103, 104, and 105.

The peripheral circuit PERI is provided on the first surface of the semiconductor substrate 70. FIG. 8 shows transistors Tr1 and Tr2 as examples of components included in the peripheral circuit PERI. In the following description, when the transistors Tr1 and Tr2 are not discriminated from each other, the transistors Tr1 and Tr2 are simply referred to as transistors Tr. Each transistor Tr includes a gate insulating film, a gate electrode, and a source and a drain (not shown) provided on the semiconductor substrate 70.

The plurality of conductor layers 101 are provided on the first surface of each of the gate electrode, the source, and the drain of the transistor Tr1 and the gate electrode, the source, and the drain of the transistor Tr2. The plurality of conductor layers 102 are respectively coupled to the first surfaces of the plurality of conductor layers 101.

Each of the plurality of conductor layers 103 is coupled to the first surface of the conductor layer 102 of the plurality of conductor layers 102 which corresponds to the conductor layer 103. The conductor layers 103-1 and 103-2 are respectively coupled to the transistors Tr1 and Tr2.

The conductor layers 104-1 and 104-2 are respectively coupled to the first surfaces of the conductor layers 103-1 and 103-2.

The conductor layers 105-1 and 105-2 are respectively coupled to the first surfaces of the conductor layers 104-1 and 104-2. The first surfaces of the plurality of conductor layers 105 are provided so as to be flush with the first surface of the insulator layer 47.

The insulator layer 60 is provided on the first surfaces of the insulator layer 47 and the plurality of conductor layers 105. The insulator layer 60 contains, for example, silicon oxide.

The plurality of conductor layers 106 are provided on the same layer as the insulator layer 60. The plurality of conductor layers 106 contain, for example, copper. The conductor layers 106-1 and 106-2 are respectively coupled to the first surfaces of the conductor layers 105-1 and 105-2. The first surfaces of the plurality of conductor layers 106 are provided so as to be flush with the first surface of the insulator layer 60. The plurality of conductor layers 106 function as a plurality of connection pads for electrically coupling the circuit chip 1-1 and the memory chip 1-2. The connection pads are also called bonding pads.

### 1.1.4.2.2 Memory Chip

The sectional structure of the memory chip 1-2 will be subsequently described with reference to FIG. 8.

The memory chip 1-2 includes, for example, a plurality of conductor layers 201, 202, 203, 204, 205, 206, and 207, a conductor layer 38, insulator layers 45, 46, 48, and 61, and the memory cell array 10.

Each of the plurality of conductor layers 201 to 207 functions as, for example, a columnar contact or interconnect. The plurality of conductor layers 201 include conductor layers 201-1 and 201-2. The plurality of conductor layers 202 include conductor layers 202-1 and 202-2. The plurality of conductor layers 203 include conductor layers 203-1 and 203-2. The plurality of conductor layers 204 include conductor layers 204-1 and 204-2. The plurality of conductor layers 205 include conductor layers 35 (205) and 205-1. The plurality of conductor layers 206 include conductor layers 206-1. The plurality of conductor layers 207 include conductor layers 207-1.

In the memory chip 1-2, the insulator layer 61 is provided on the first surface of the circuit chip 1-1. The insulator layer 61 contains, for example, silicon oxide.

The plurality of conductor layers 201 are provided on the same layer as the insulator layer 61. The plurality of conductor layers 201 contain, for example, copper. The conductor layers 201-1 and 201-2 are respectively coupled to the first surfaces of conductor layers 106-1 and 106-2. The second surfaces of the plurality of conductor layers 201 are provided so as to be flush with the second surface of the insulator layer 61.

The plurality of conductor layers 201 function as a plurality of connection pads for electrically coupling the circuit chip 1-1 and the memory chip 1-2 to each other. With the above arrangement, the circuit chip 1-1 and the memory chip 1-2 are electrically coupled to each other through the plurality of conductor layers 106 and 201.

The insulator layer 46 is provided on the first surfaces of the insulator layer 61 and the plurality of conductor layers 201. The insulator layer 46 is internally provided with, for example, the plurality of conductor layers 202 to 206, portions of the plurality of conductor layers 207, and a portion of the memory cell array 10.

The memory cell array 10 is provided such that the conductor layer 30 is placed on one side, and the conductor layer 35 (205) is placed on the other side in the Z direction.

The conductor layer 202-1 is provided on the first surface of the conductor layer 201-1. The conductor layer 203-1 is coupled to the first surface of the conductor layer 202-1. The conductor layer 204-1 is coupled to the first surface of the conductor layer 203-1. The conductor layer 35 (205) is coupled to the first surface of the conductor layer 204-1. The above arrangement allows the conductor layer 35 (205) to be coupled to the transistor Tr1. That is, the bit lines BL of the memory cell array 10 are coupled to the peripheral circuit PERI.

The conductor layer 202-2 is provided on the first surface of the conductor layer 201-2. The conductor layer 203-2 is provided on the first surface of the conductor layer 202-2. The conductor layer 204-2 is provided on the first surface of the conductor layer 203-2. The conductor layer 205-1 is provided on the first surface of the conductor layer 204-2. The conductor layer 206-1 is provided on the first surface of the conductor layer 205-1. The conductor layer 207-1 is provided on the first surface of the conductor layer 206-1. The conductor layer 207-1 extends in the Z direction. The portion of the conductor layer 207-1 which is located on one side protrudes from the insulator layer 46. The conductor layer 207-1 functions as, for example, a columnar contact.

For example, the insulator layer 45 is provided on a portion of the first surface of the conductor layer 30 and a portion of the first surface of the insulator layer 46 except for a portion of the first surface which surrounds the conductor layer 207-1.

The conductor layer 38 is provided on the first surface of the insulator layer 45, the portion of the first surface of the conductor layer 30 on which the insulator layer 45 is not provided, the first surface of the conductor layer 207-1, and the portion of the first surface of the insulator layer 46 which surrounds the conductor layer 207-1. The conductor layer 38 functions as, for example, an interconnect extending in the Y direction. The conductor layer 38 contains, for example, aluminum.

The conductor layer 38 coupled to the conductor layer 207-1 includes, for example, a portion exposed on the first surface of the semiconductor memory device 1 above the insulator layer 46. This portion functions as an electrode pad PD. The electrode pad PD functions as an extraction pad for connection to an external device of the semiconductor memory device 1. For example, this arrangement allows the electrode pad PD and the transistor Tr2 to be coupled to each other through the conductor layers 101 to 106 and 201 to 207. That is, the electrode pad PD is coupled to the peripheral circuit PERI.

Although not shown, the portion of the conductor layer 38 which is in contact with the conductor layer 30 is coupled to the peripheral circuit PERI of the circuit chip 1-1 with an arrangement similar to that of the conductor layers 201 to 207. This allows the conductor layer 30 and the peripheral circuit PERI to be coupled to each other through the conductor layers 38, 101 to 106, and 201 to 207.

Although not shown, each of the conductor layers 31 to 34 of the memory cell array 10 is coupled to the peripheral circuit PERI of the circuit chip 1-1 with an arrangement similar to that of the conductor layers 201 to 205 and the like. This allows each of the conductor layers 31 to 34 and the peripheral circuit PERI to be coupled to each other through components such as the conductor layers 101 to 106 and 201 to 205.

The insulator layer 48 is stacked on the portion of the conductor layer 38 which is located on one side except for the portion provided with the electrode pad PD. The insulator layer 48 functions as, for example, a passivation film.

### 1.1.4.2.3 Sectional Structure of Connection Pad

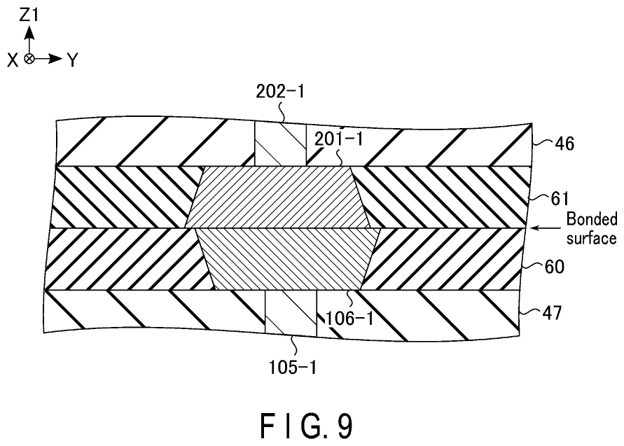

The sectional structure of a connection pad will be described with reference to FIG. 9. FIG. 9 is a sectional view showing an example of the sectional structure of a connection pad of the semiconductor memory device according to the embodiment.

Although the portion where the conductor layer 106-1 is coupled to the conductor layer 201-1 will be described below, the same applies to the portion where each of the remaining conductor layers 106 is coupled to a corresponding one of the conductor layers 201.

On the bonding surface where the circuit chip 1-1 is bonded to the memory chip 1-2, the area of the conductor layer 106-1 is, for example, the same as the area of the conductor layer 201-1. If the conductor layers 106-1 and 201-1 are copper, the conductor layers 106-1 and 201-1 are integrated to make it difficult to check the boundary between the copper layers. However, it is possible to check the bonding based on the bonded shape distortion between the conductor layers 106-1 and 201-1 due to a positional shift at the time of bonding. Alternatively, it is possible to check the bonding based on the positional shift between the copper barrier metals. That is, it is possible to check the bonding based on the occurrence of a discontinuous portion on a side surface.

If the conductor layers 106-1 and 201-1 are formed by the damascene method, each side surface has a tapered shape. Accordingly, the side wall of the conductor layer 106-1 is not aligned with the side wall of the conductor layer 201-1. For this reason, a section of the portion where the conductor layers 106-1 and 201-1 are bonded to each other along the Z direction has a non-rectangular shape.

When the conductor layers 106-1 and 201-1 are bonded to each other, the first surface, the second surface, and the side surfaces of each copper layer are covered by the barrier metal. In contrast to this, a general interconnect layer using copper is provided with an insulating layer (silicon nitride or silicon carbide with nitrogen) having an antioxidant function for copper on the upper surface of the copper layer but is not provided with any barrier metal. Accordingly, it is possible to discriminate the above interconnect layer from a general interconnect layer without any positional shift at the time of bonding.

### 1.2 Manufacturing Method

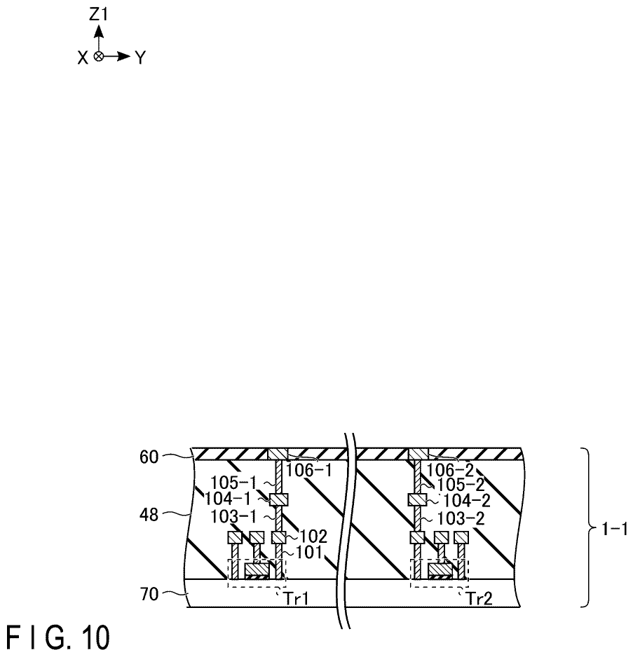

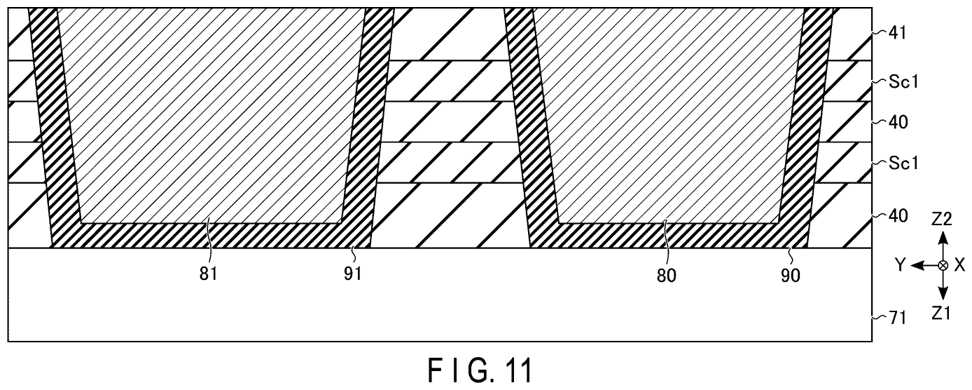

A method of manufacturing the semiconductor memory device 1 according to the embodiment will be described with reference to FIGS. 10, 11, 12, 13, 14, 15, 16, 17, 18, 19, 20, 21, 22, 23, 24, 25, and 26. FIGS. 10, 11, 12, 13, 14, 15, 16, 17, 18, 19, 20, 21, 22, 23, 24, 25, and 26 are sectional views for explaining an example of the method of manufacturing the semiconductor memory device according to the embodiment. FIGS. 11, 13, 14, 19, 20, 21, 22, 23, 24, and 25 show a region corresponding to FIG. 7. FIGS. 10, 12, 15, 16, 17, 18, and 26 show a region corresponding to FIG. 8.

As shown in FIG. 10, first of all, the circuit chip 1-1 is formed.

A portion of the memory chip 1-2 is then formed as described below.

First of all, the two insulator layers 40, the insulator layer 41, and two sacrificial layers Sc1 are formed on the second surface of a semiconductor substrate 71 in the order of the insulator layer 40, the sacrificial layer Sc1, the insulator layer 40, the sacrificial layer Sc1, and the insulator layer 41. The two sacrificial layers Sc1 correspond to the two conductor layers 31.

A plurality of concave portions corresponding to the plurality of memory pillars MP and the plurality of members SLT are formed by anisotropic etching using a mask. The anisotropic etching in this step is, for example, RIE (Reactive Ion Etching). After the mask is removed, as shown in FIG. 11, a plurality of stopper layers 80 and 81 and a plurality of insulator layers 90 and 91 are formed in correspondence with the plurality of memory pillars MP and the plurality of members SLT. The plurality of insulator layers 90 are formed first on the inner surfaces of the plurality of concave portions corresponding to the plurality of memory pillars MP. The plurality of insulator layers 91 are formed on the inner surfaces of the plurality of concave portions corresponding to the plurality of members SLT. The plurality of stopper layers 80 are then formed so as to fill the insides of the plurality of concave portions on which the plurality of insulator layers 90 are formed. The plurality of stopper layers 81 are formed so as to fill the insides of the plurality of concave portions on which the insulator layers 91 are formed. The plurality of stopper layers 80 and 81 contain, for example, tungsten (W), titanium nitride (TiN), or aluminum oxide (AlO). The plurality of insulator layers 90 and 91 contain, for example, silicon oxide.

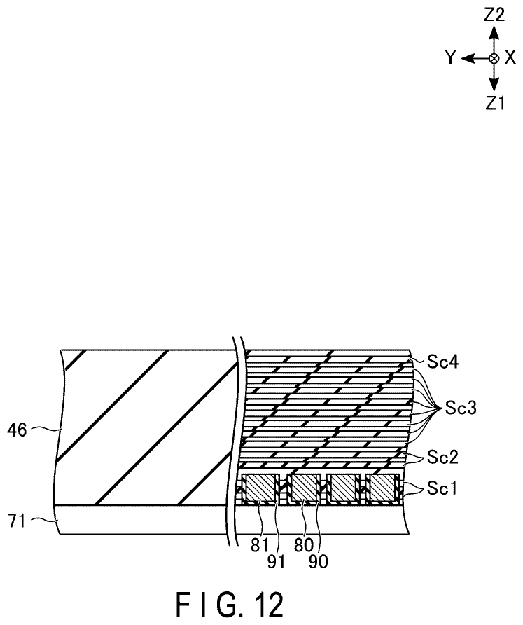

The portion of the insulator layer 41 which is located on the other side relative to the plurality of stopper layers 80 and 81 and the plurality of insulator layers 90 and 91 is formed. In addition, as shown in FIG. 12, two sacrificial layer Sc2, a plurality of sacrificial layers Sc3, a sacrificial layer Sc4, the two insulator layers 42, the plurality of insulator layers 43, the insulator layer 44, and the insulator layer 46 are formed. The two sacrificial layers Sc2 correspond to the two conductor layers 32. The plurality of sacrificial layers Sc3 correspond to the plurality of conductor layers 33. The sacrificial layer Sc4 corresponds to the conductor layer 34.

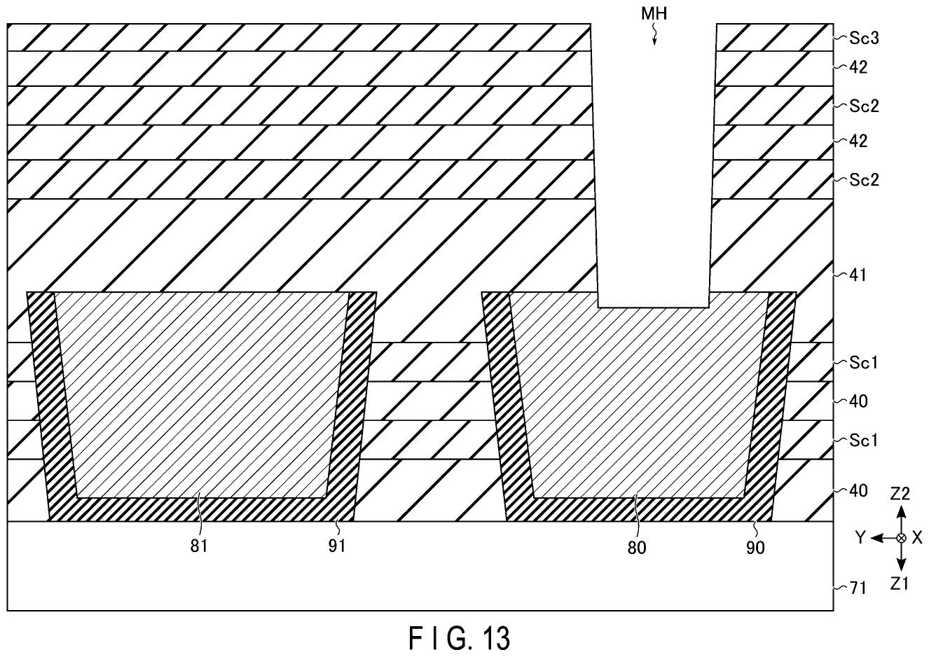

Subsequently, as shown in FIG. 13, a plurality of memory holes MH corresponding to the plurality of memory pillars MP are formed by anisotropic etching using a mask. The anisotropic etching in this step is, for example, RIE. Thereafter, the mask is removed. In this step, the stopper layer 80 functions as a stopper in the etching processing. With this arrangement, the bottom surface of the memory hole MH is located, for example, on the other side relative to the first surface of the stopper layer 80 and at the same height as the second surface of the stopper layer 80 or at a position on one side relative to the height.

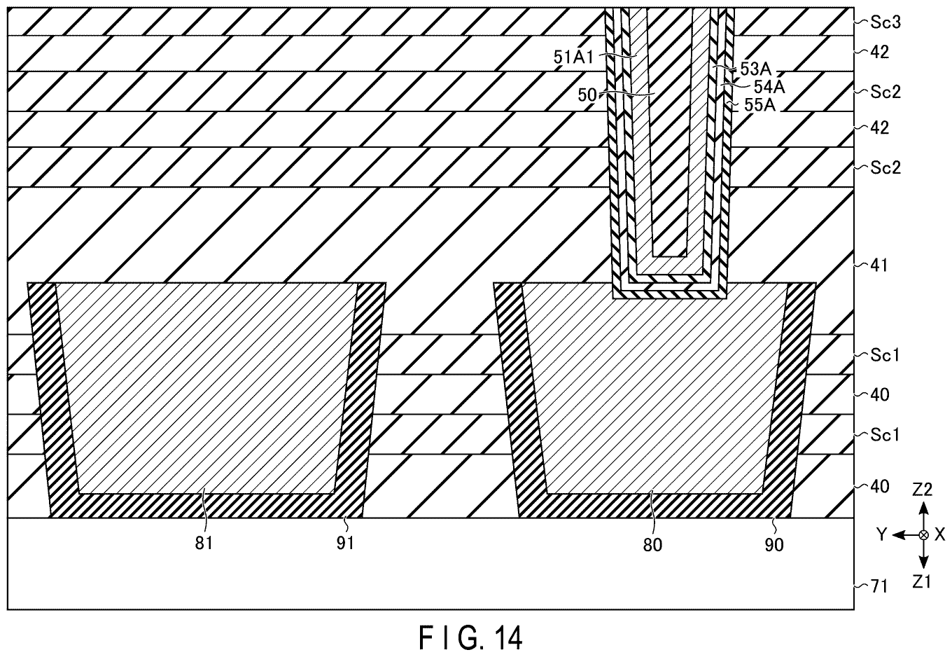

As shown in FIG. 14, the core member 50, a semiconductor portion 51A1, a tunnel insulating film 53A, a charge storage film 54A, and a block insulating film 55A are formed. The semiconductor portion 51A1 is formed so as to cover the side surface and the first surface of the core member 50. The tunnel insulating film 53A is formed so as to cover the side surface and the first surface of the semiconductor portion 51A1. The charge storage film 54A is formed so as to cover the side surface and the first surface of the tunnel insulating film 53A. The block insulating film 55A is formed so as to cover the side surface and the first surface of the charge storage film 54A.

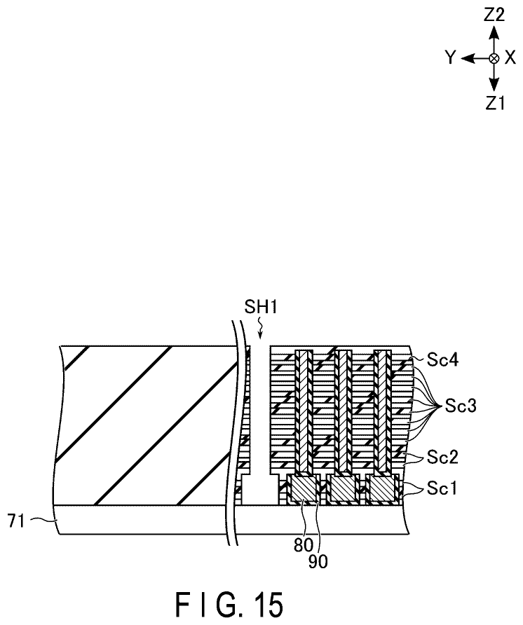

As shown in FIG. 15, a plurality of slits SH1 are formed. More specifically, a predetermined region where the plurality of members SLT are expected to be formed is removed by anisotropic etching using a mask including opening portions corresponding to the plurality of members SLT. This forms the plurality of slits SH1. In this step, the anisotropic etching is, for example, RIE. Thereafter, the mask is removed.

The sacrificial layers Sc1 to Sc4 are replaced by the conductor layers 31 to 34. More specifically, the sacrificial layers Sc1 to Sc4 are selectively removed through the plurality of slits SH1 by, for example, wet etching with hot phosphoric acid. A conductor is then embedded in the spaces formed by removing the sacrificial layers Sc1 to Sc4. This forms the conductor layers 31 to 34. In the following description, the processing of replacing the sacrificial layers Sc1 to Sc4 with the conductor layers 31 to 34 will be simply referred to as replace processing.

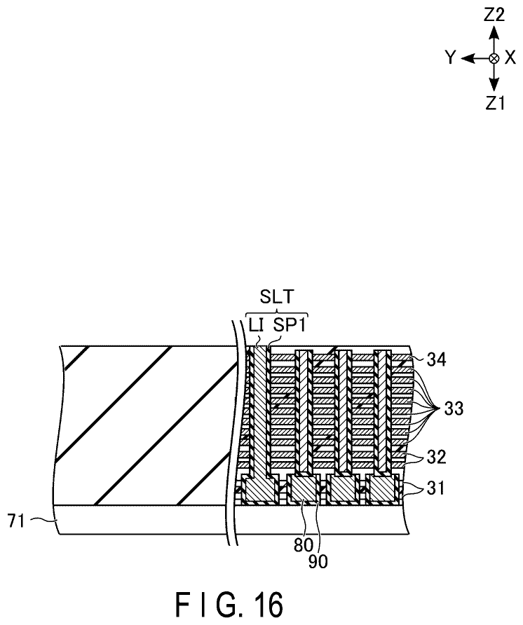

Subsequently, as shown in FIG. 16, the plurality of members SLT are formed. More specifically, for example, the spacer SP1 is formed so as to cover the side surfaces and the bottom surfaces of the plurality of slits SH1. In addition, the core portion LI is formed so as to fill the plurality of slits SH1 on which the spacer SP1 is formed. Although not shown, in this step, the void VD2 can be formed in the core portion LIB.

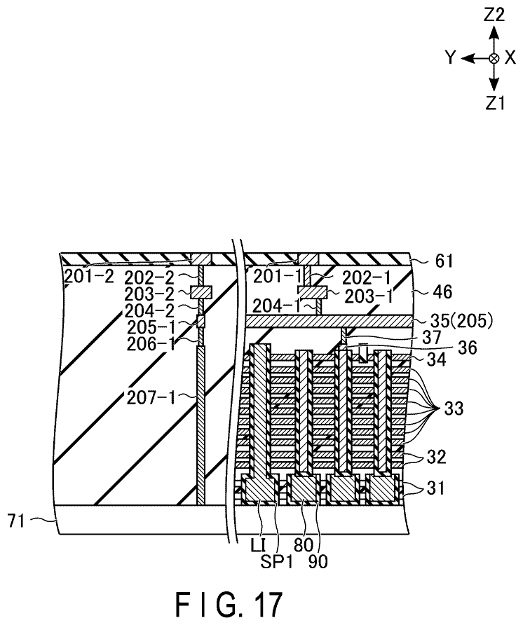

In addition, as shown in FIG. 17, the conductor layers 35 to 37 and 201 to 207, the plurality of members SHE, and the insulator layer 61 are formed.

With the above steps, portions of the memory chip 1-2 are formed.

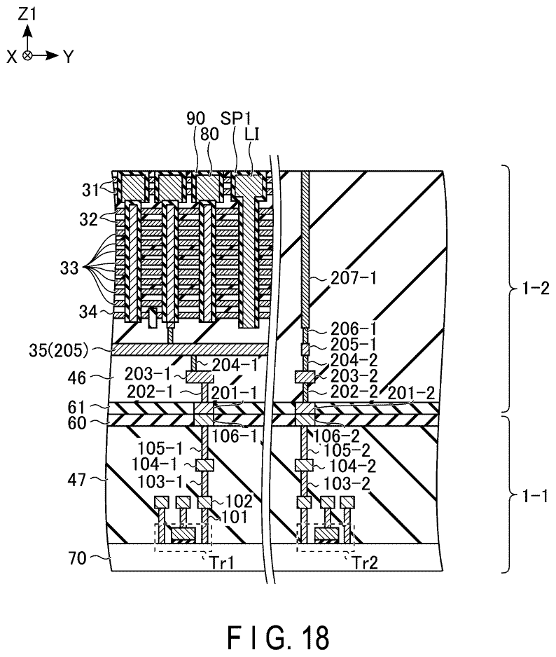

The portions of the circuit chip 1-1 and the memory chip 1-2 are bonded to each other by bonding processing. More specifically, the plurality of conductor layers 106 functioning as the connection pads of the circuit chip 1-1 and the plurality of conductor layers 201 functioning as the connection pads of the memory chip 1-2 are arranged to face each other. The connection pads facing each other are bonded to each other by annealing. Thereafter, as shown in FIG. 18, the semiconductor substrate 71 is removed by, for example, CMP (Chemical Mechanical Polishing) processing.

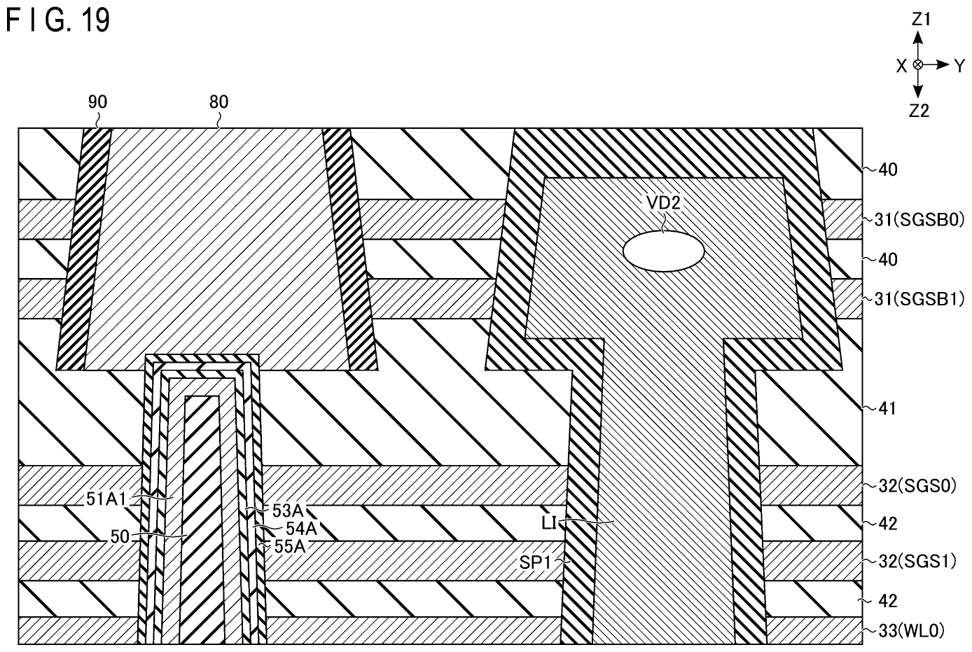

As shown in FIG. 19, the portion of the memory chip 1-2 which is located on one side is removed so as to expose the stopper layer 80 by, for example, further CMP processing.

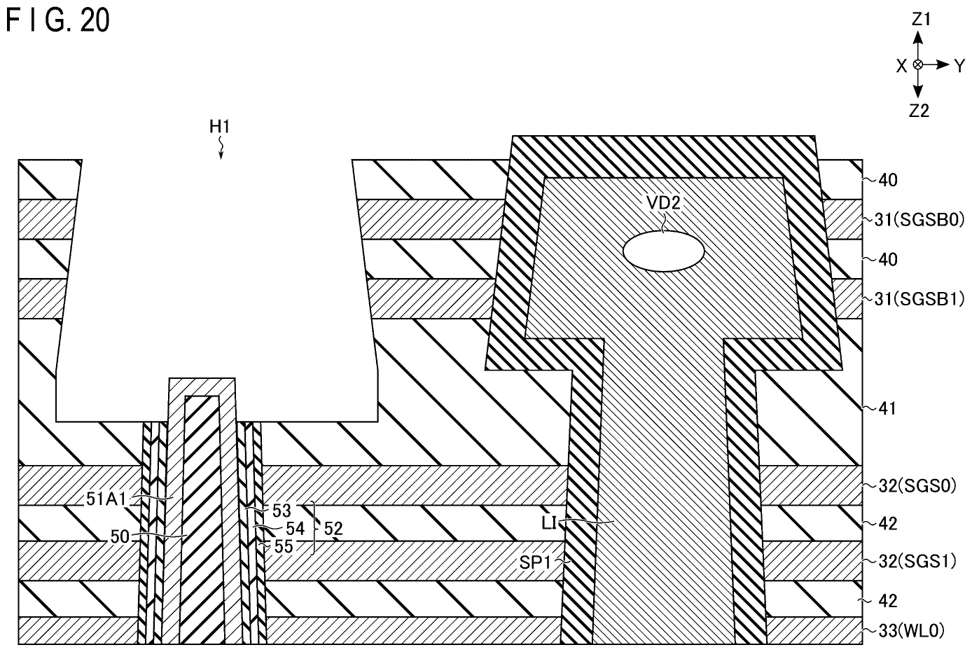

A plurality of holes H1 are formed by removing the plurality of stopper layers 80. In addition, as shown in FIG. 20, the insulator layer 90, a portion of the tunnel insulating film 53A, a portion of the charge storage film 54A, a portion of the block insulating film 55A, and the portion of the insulator layer 41 which is exposed on the bottom surface of the hole H1 are removed through the hole H1. In addition, the portion of the insulator layer 40 which is located on one side is removed. With this processing, the stacked film 52 including the tunnel insulating film 53, the charge storage film 54, and the block insulating film 55 is formed from the tunnel insulating film 53A, the charge storage film 54A, and the block insulating film 55A. Although the portion of the spacer SP1 which is located on one side is also removed in this step, the step is executed so as not to expose the core portion LI. In the step, the semiconductor portion 51A1 is hardly removed and is exposed in the hole H1. Accordingly, the core member 50 is not exposed.

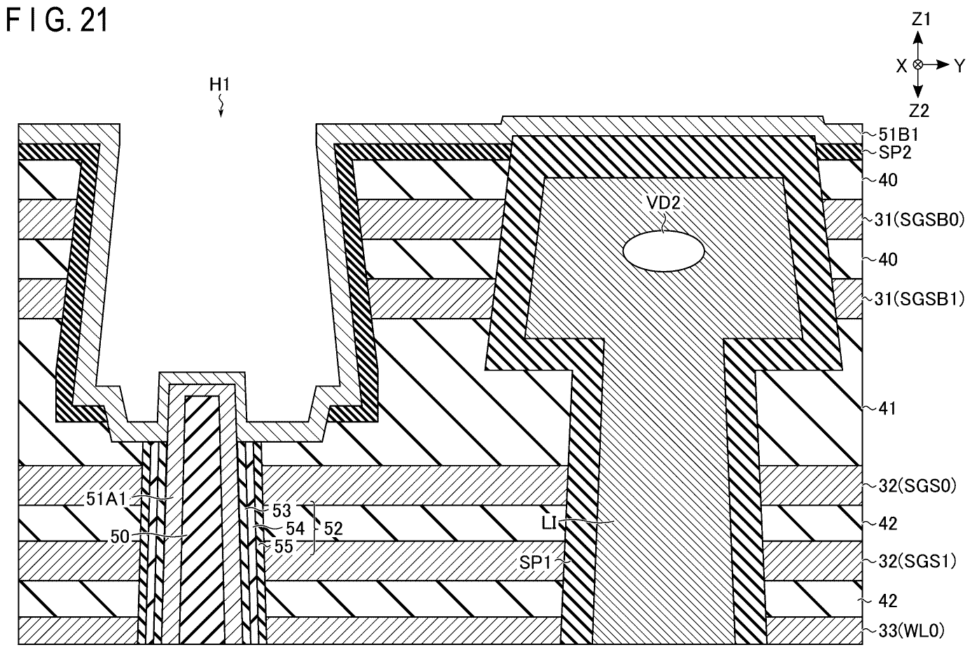

In addition, as shown in FIG. 21, the spacer SP2 and a semiconductor portion 51B1 are formed. The semiconductor portion 51B1 corresponds to the semiconductor portion 51B. More specifically, first of all, for example, the spacer SP2 is formed on the inner surface of the hole H1 and the first surface of the insulator layer 40. Subsequently, the portion of the spacer SP2 which is formed on a portion of the bottom surface of the hole H1 is removed by RIE. In this removing processing, for example, in a range overlapping the removed portion viewed from above, the portion of the insulator layer 41 which is located on one side relative to the two conductor layers 32 is also removed. The semiconductor portion 51B1 is then formed on the first surface of the spacer SP1, the first surface and the side surface of the spacer SP2, the portion of the semiconductor portion 51A1 which is located on one side, the first surface of the stacked film 52, and the first surface of the insulator layer 41 which is exposed in the hole H1.

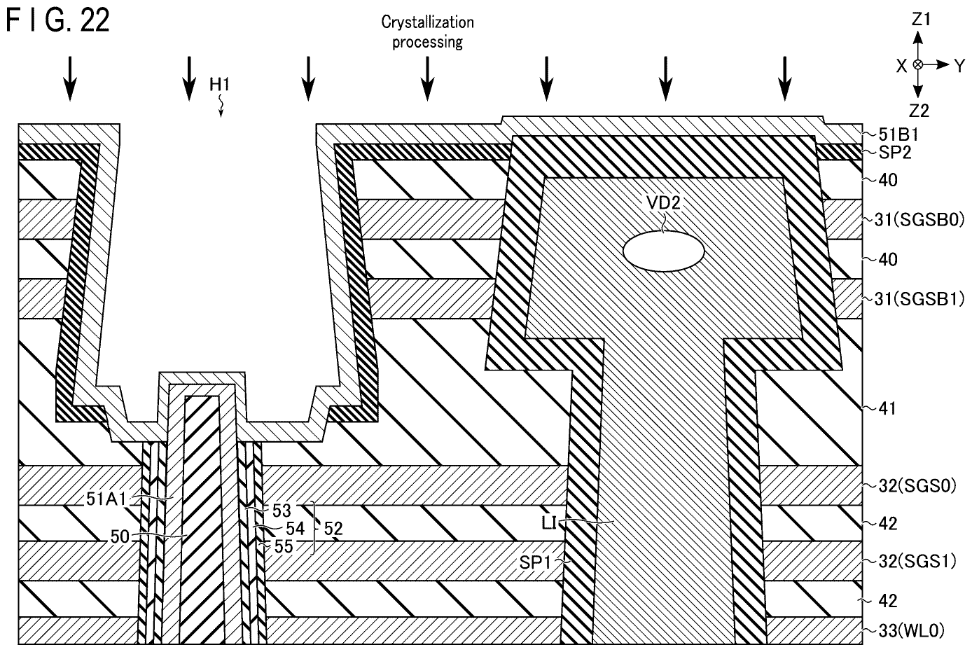

As shown in FIG. 22, crystallization processing is executed. The crystallization processing is, for example, LSA (laser spike anneal) processing. With this processing, the semiconductor portion 51A1 and the semiconductor portion 51B1 are integrated.

The portion of the semiconductor portion 51A1 and the semiconductor portion 51B1 after integrated by the crystallization processing which is located on one side relative to the spacer SP2 is removed. This forms the semiconductor film 51 corresponding to each memory pillar MP.

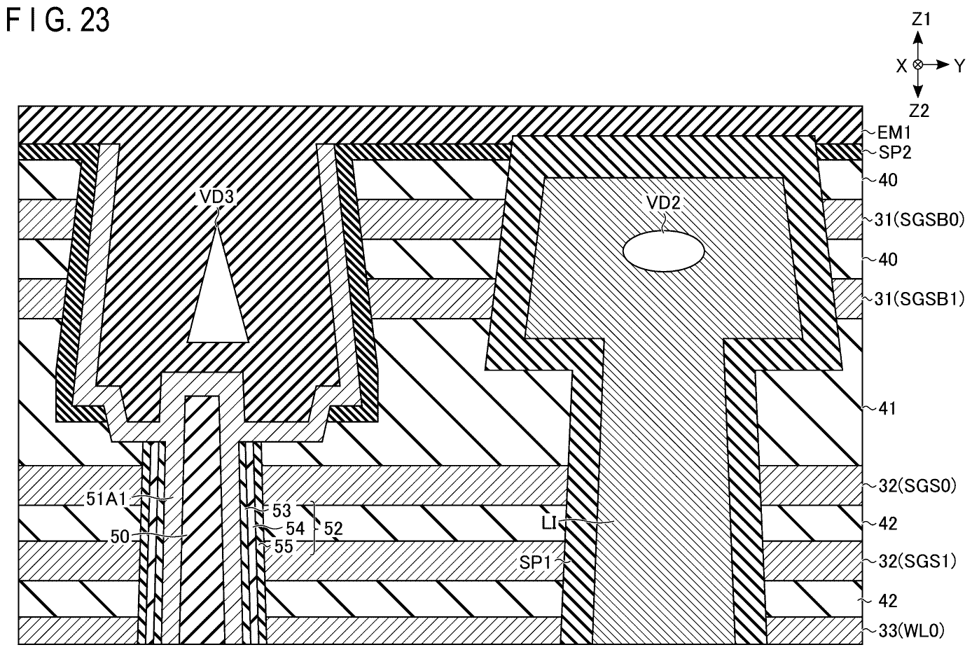

As shown in FIG. 23, an insulator layer EM1 is formed on the semiconductor film 51, the first surface of the spacer SP1, and the first surface of the spacer SP2 so as to fill the plurality of holes H1. In this case, owing to the filling of the hole H1, for example, the insulator layer EM1 includes a void VD3 in a portion corresponding to the hole H1.

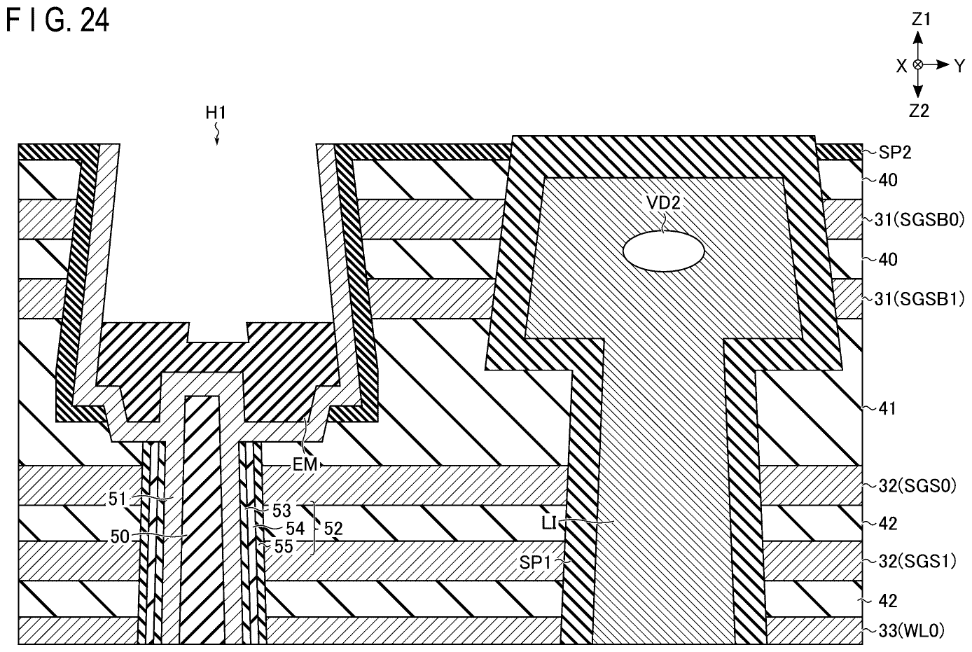

As shown in FIG. 24, for example, a portion of the insulator layer EM1 is removed. This forms the hole H1 having the insulator portion EM corresponding to each memory pillar MP in the bottom surface. This step is executed so as to locate the insulator portion EM on the other side relative to the two conductor layers 31. Note that the first surface of the insulator portion EM can have, for example, a portion receding to the other side in correspondence with the void VD3.

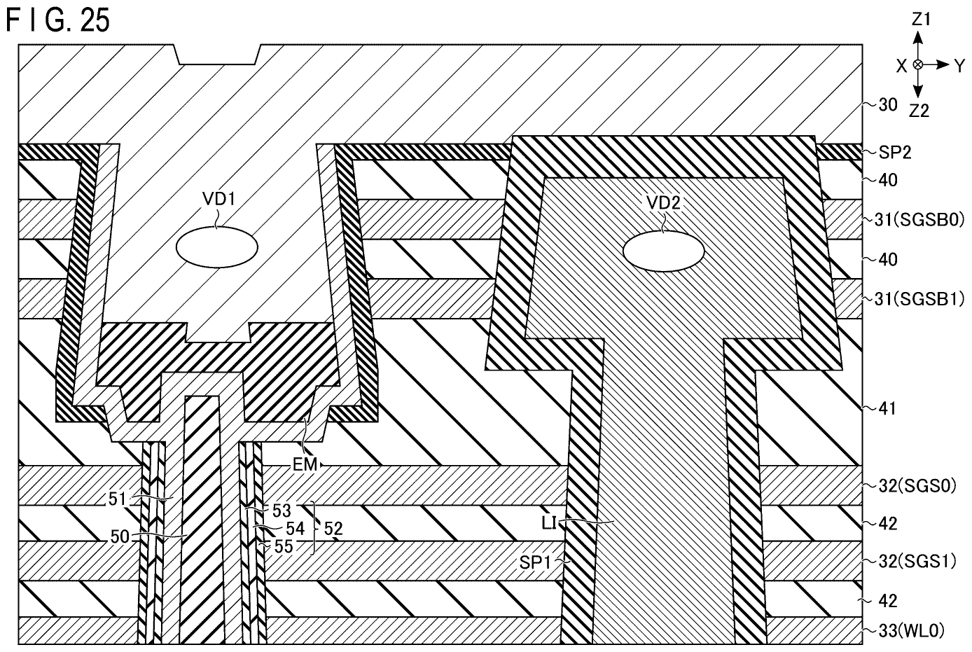

As shown in FIG. 25, the conductor layer 30 is formed on the semiconductor film 51, the first surface of the insulator layer EM, the first surface of the spacer SP1, and the first surface of the spacer SP2 so as to fill the plurality of holes H1. The portion of the conductor layer 30 which is embedded in each hole H1 corresponds to the conductor portion 30B. In this step, the Schottky junction between the conductor portion 30B and the semiconductor film 51 is formed. The portion of the conductor layer 30 which is formed on one side relative to the first surface of the spacer SP2 corresponds to the conductor portion 30A. The first surface of the conductor portion 30A is formed, for example, so as to be concave to the other side at portions corresponding to the plurality of memory pillars MP due to the filling of the plurality of holes H1. The second surface of the conductor portion 30B is formed, for example, so as to be convex to the other side in correspondence with the first surface of the insulator portion EM. Note that in this step, the void VD1 can be formed in the conductor portion 30B.

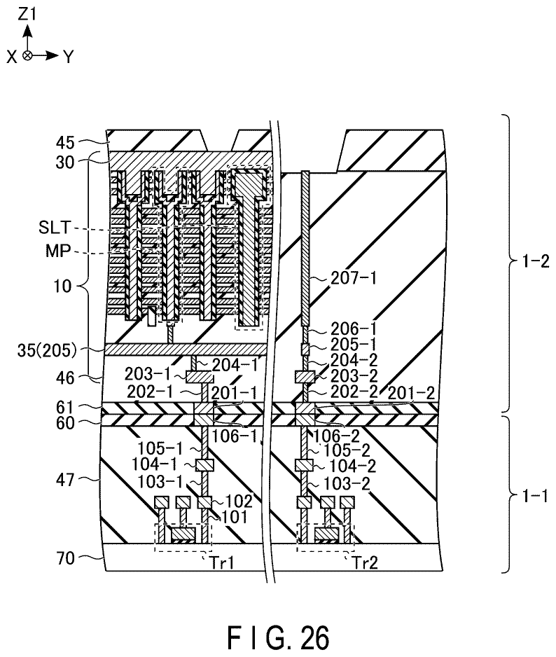

Subsequently, as shown in FIG. 26, the insulator layer 45 is formed so as to expose a portion of the first surface of the conductor layer 30 and the portion of the conductor layer 207 which is located on one side. More specifically, first of all, the insulator layer 45 is formed on the first surface of the conductor layer 30, the first surface of the insulator layer 46, and the first surface of the conductor layer 207. A portion of the insulator layer 45 and a portion of the insulator layer 46 are removed so as to expose the portion of the conductor layer 207 which is located on one side. In a region corresponding to the memory cell array 10, a portion of the insulator layer 45 is removed so as to expose a portion of the first surface of the conductor layer 30.

The conductor layer 38 and the insulator layer 48 are formed.

With the above manufacturing steps, the semiconductor memory device 1 is manufactured.

Note that the manufacturing steps described above are merely an example, other processes may be inserted between the respective manufacturing steps, and the executing order of the manufacturing steps may be interchanged. For example, since the circuit chip 1-1 and a portion of the memory chip 1-2 are formed by using the different semiconductor substrates 70 and 71, the step of forming the circuit chip 1-1 shown in FIG. 10 and the step of forming the portion of the memory chip 1-2 shown in FIGS. 11, 12, 13, 14, 15, 16, and 17 can be proceeded concurrently.

### 1.3 Effects

According to the embodiment, the reliability of the semiconductor memory device 1 can be improved. The effects of the embodiment will be described below.

In the semiconductor memory device 1 according to the embodiment, the memory cell array 10 includes the conductor layers 30 and 31, the plurality of conductor layers 33, and the memory pillars MP. The conductor layer 31 corresponds to the selection gate line SGSB. The plurality of conductor layers 33 correspond to the plurality of word lines WL. The conductor layer 31 is provided so as to be separated from the plurality of conductor layers 33 on one side relative to the plurality of conductor layers 33. The conductor layer 30 is provided on one side relative to the plurality of conductor layers 33. The conductor layer 30 corresponds to the source line SL. The conductor layer 30 includes the conductor portions 30A and 30B coupled to each other. The conductor portion 30A is included on one side relative to the conductor layer 31. The conductor portion 30B is included on the other side relative to the conductor portion 30A. The conductor portion 30B extends in the Z direction in accordance with the memory pillar MP. The memory pillar MP includes the core member 50, the semiconductor film 51, and the stacked film 52. The core member 50 extends from a position on the other side relative to the plurality of conductor layers 33 to a position on the other side relative to the conductor portion 30B. The semiconductor film 51 includes the semiconductor portions 51A and 51B coupled to each other. The semiconductor portion 51A covers the side surface of the core member 50 and the surface of the core member 50 located on one side. The semiconductor portion 51B is included on one side relative to the plurality of conductor layers 33. The semiconductor portion 51B is in contact with the conductor portion 30B so as to cover the side surface of the conductor portion 30B. The stacked film 52 covers the side surface of the semiconductor portion 51A. The above arrangement can suppress the occurrence of variation in the height of the conductor portion 30B protruding from the conductor portion 30A to the other side in correspondence with the memory pillar MP. In addition, in the manufacturing process, it is possible to suppress the intrusion of the conductive material of the source line SL into the core member 50. Therefore, it is possible to improve the reliability of the semiconductor memory device 1.

The above contents will be described with reference to a comparative example including memory pillars uniformly extending in the Z direction. A memory pillar according to the comparative example is embedded with a source line portion up to the same height as a selection gate line located on one side relative to a plurality of word lines on one side of the memory pillar. In an XY plane, the sectional area of the memory pillar according to the comparative example at the same height as the selection gate line is equal to or less than that of the memory pillar at the same height as the word line of the plurality of word lines which is located on one side. In the manufacturing process according to the comparative example, in manufacturing a memory chip portion, after a memory hole is formed, for example, an epitaxial film is grown on a substrate exposed on a bottom portion of the memory hole. A memory pillar is formed on the epitaxial film. After replace processing and bonding between a memory chip and a circuit chip, the epitaxial film is removed. In addition, for example, the portion of the core member which is located on one side of the memory pillar is removed up to the same height as the selection gate line. A source line is then formed so as to fill the space formed by the removal with a conductor. In the manufacturing process according to the comparative example, an epitaxial film is formed to perform, for example, depth control in forming a space to be filled with a conductor corresponding to the source line (in removing a core member portion to the same height as a selection gate line). However, since it is difficult to control the thickness of an epitaxial film, variation occurs in the height (depth) of the joint portions between source lines and semiconductor films in a plurality of memory pillars. This causes variation in the characteristics of memory pillars.

According to the embodiment, as described with reference to FIG. 11, the stopper layer 80 and the insulator layer 90 corresponding to the conductor portion 30B are formed so as to fill the concave portion formed in the structure formed by stacking the two sacrificial layers Sc1. In addition, the structure corresponding to the portion of the memory pillar MP which includes the stacked film 52 is formed on the other side relative to the stopper layer 80 and the insulator layer 90, as described with reference to FIG. 14. As described above, the structure corresponding to the conductor portion 30B is formed by filling the concave portion without forming any epitaxial film. This makes it possible to suppress the occurrence of variation in the height of the conductor portion 30B.

In addition, a core member sometimes includes a void due to an embedding step at the time of forming the core member. For this reason, in the comparative example, when a conductor corresponding to a source line is embedded after the portion of the core member which is located on one side of the memory pillar is removed, a conductive material may intrude into the void. This may cause variation in the characteristics of memory pillars.

According to the embodiment, as described with reference to FIG. 20, in forming the hole H1 corresponding to the conductor portion 30B, the core member 50 is not exposed, and only the first surface of the stacked film 52 and a portion of the semiconductor portion 51A1 are exposed. That is, the core member 50 is not removed even partially. As described with reference to FIGS. 23 and 24, in the embodiment, the insulator layer EM1 is formed so as to fill the plurality of holes H1 before the formation of the conductor layer 30. With this processing, in the semiconductor memory device 1 according to the embodiment, the insulator portion EM is provided between the conductor portion 30B and the core member 50 and the semiconductor portion 51A in the Z direction. Therefore, even if the core member 50 includes a void, the conductive material of the source line SL does not intrude into the void.

As has been described above, according to the embodiment, the reliability of the semiconductor memory device 1 can be improved.

### 2 Modification

The above embodiment can be variously modified. Modifications of the semiconductor memory device will be described below.

### 2.1 First Modification

The above embodiment has exemplified the case where each NAND string NS includes the two selection transistors ST2 and the two selection transistors STB. However, the present invention is not limited to this. Each NAND string NS may include one each of the selection transistors ST2 and the selection transistors STB. In the following description, the arrangement of the semiconductor memory device according to the first modification will be described, focusing on differences from the arrangement of the semiconductor memory device according to the embodiment.

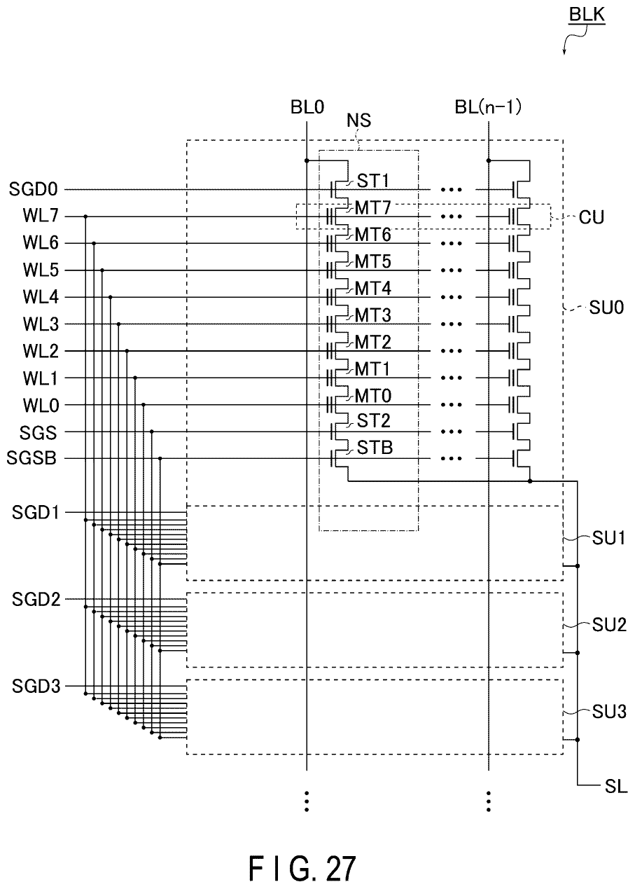

The circuit arrangement of the memory cell array 10 of the semiconductor memory device 1 according to the first modification will be described with reference to FIG. 27. FIG. 27 is a circuit diagram showing an example of the circuit arrangement of the memory cell array of the semiconductor memory device according to the first modification.

In the semiconductor memory device 1 according to the first modification, each NAND string NS includes one selection transistor ST2 and one selection transistor STB.

One terminal of the selection transistor ST2 is coupled to the other terminal of each of the memory cell transistors MT0 to MT7 coupled in series. One terminal of the selection transistor STB is coupled to the other terminal of the selection transistor ST2. The other terminal of the selection transistor STB is coupled to the source line SL.

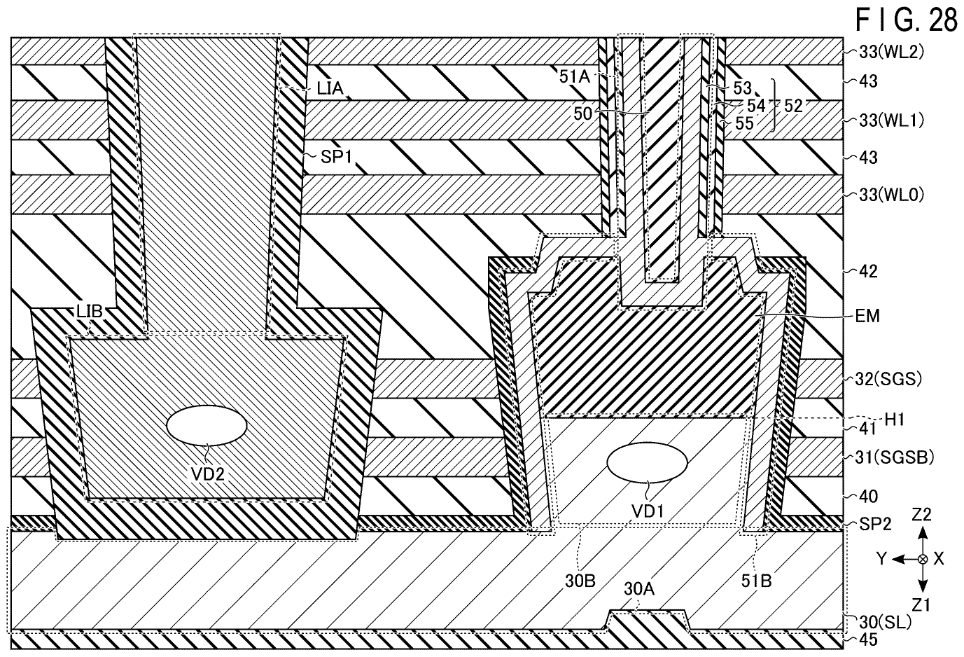

The sectional structure of the memory cell array 10 of the semiconductor memory device 1 according to the first modification will be described next with reference to FIG. 28. FIG. 28 is a sectional view showing an example of the sectional structure of the memory cell array of the semiconductor memory device according to the first modification. FIG. 28 corresponds to FIG. 7 in the embodiment.

The memory cell array 10 according to the first modification includes one each of the conductor layers 31 and 32. The conductor layers 31 and 32 are provided on one side relative to the core member 50. In addition, since the memory cell array 10 includes one each of the conductor layers 31 and 32, the memory cell array 10 also includes one each of the insulator layers 40 and 42.

The second surface of the conductor portion 30B is located at a height H1 on one side relative to the conductor layer 32. That is, the conductor portion 30B extends through the conductor layer 31 but does not extend through the conductor layer 32. Note that the first modification exemplifies the case where the second surface of the conductor portion 30B is flat.

With the arrangement of the conductor portion 30B described above, the conductor portion 30B is not included in the same height as the selection gate line SGS, but the insulator portion EM is included.

A method of manufacturing the semiconductor memory device 1 according to the first modification can be substantially the same as the method of manufacturing the semiconductor memory device according to the embodiment. In the manufacturing method according to the first modification, a portion of the insulator layer 42 is removed through the hole H1 instead of a portion of the insulator layer 41 in the step described with reference to FIG. 20 in the embodiment. In the manufacturing method according to the first modification, a step corresponding to the step described with reference to FIG. 24 in the embodiment is executed such that the first surface of the insulator portion EM is located between the conductor layers 31 and 32.

The first modification can also obtain effects similar to those of the embodiment.

According to the first modification, the portion where the conductor layer 32 intersects the memory pillar MP is not provided with the stacked film 52 including the tunnel insulating film 53, the charge storage film 54, and the block insulating film 55. With this arrangement, in the selection transistor ST2, variation in the threshold voltage of the transistor due to, for example, the discharge of accumulated electrons is suppressed. This makes it possible to improve the controllability of the selection transistor ST2.

### 2.2 Second Modification

The above embodiment and the first modification have exemplified the case where the conductor portion 30B is in contact with the insulator portion EM. However, the present invention is not limited to this. The conductor portion 30B and the insulator portion EM may be provided through a block film so as not to be in direct contact with each other. The arrangement of a semiconductor memory device according to the second modification will be described below, focusing on differences from the arrangement of the semiconductor memory device according to the first modification.

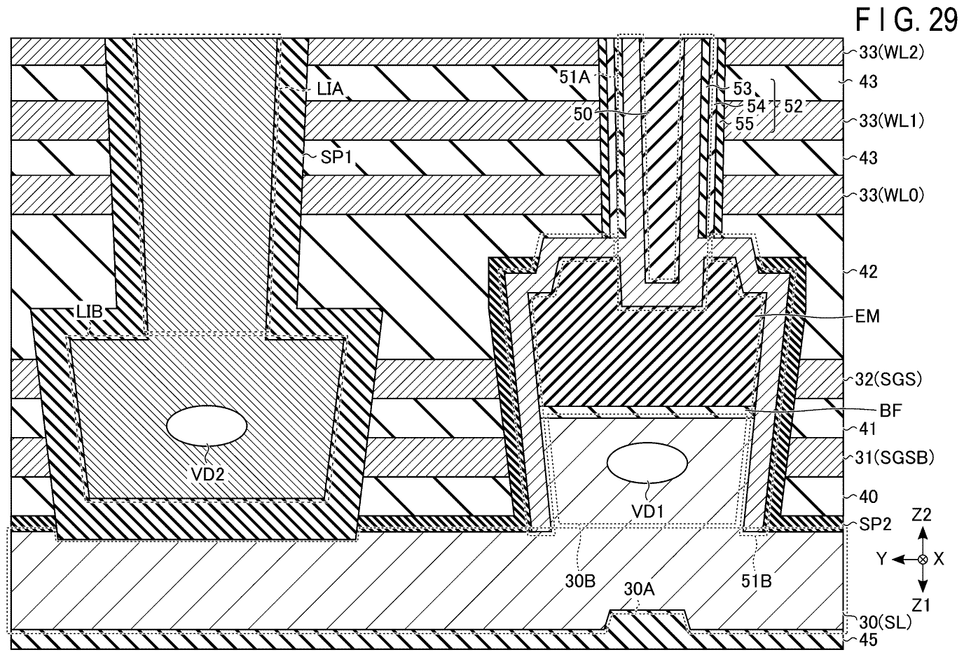

The sectional structure of the memory cell array 10 of the semiconductor memory device 1 according to the second modification will be described with reference to FIG. 29. FIG. 29 is a sectional view showing an example of the sectional structure of the memory cell array of the semiconductor memory device according to the second modification. FIG. 29 corresponds to FIG. 7 in the embodiment.

A block film BF is provided on the second surface of the conductor portion 30B. The first surface of the insulator portion EM is in contact with the second surface of the block film BF. The block film BF contains, for example, a material having low permeability with respect to a gas such as fluorine (F) or hydrogen (H). In addition, the block film BF is formed of an insulating material. The insulating material includes, for example, aluminum oxide.

A method of manufacturing the semiconductor memory device 1 according to the second modification is substantially the same as the method of manufacturing the semiconductor memory device according to the embodiment except that the block film BF is formed before the formation of the conductor layer 30 after the step described with reference to FIG. 24 in the embodiment. In forming the block film BF, for example, the bottom surface and the side surface of the hole H1 formed by the step described with reference to FIG. 24 in the embodiment are covered with the insulating material forming the block film BF. Of the insulating material formed on the bottom surface and the side surface of the hole H1, the portion provided on the side surface is removed by, for example, CDE (Chemical Dry Etching) or the like. This forms, for example, the block film BF on the bottom surface of the hole H1.

The second modification can also obtain effects similar to those of the embodiment.

The second modification can, for example, prevent a deterioration in the reliability of the semiconductor memory device 1 due to a gas such as fluorine (F) and hydrogen (H).

In addition, in manufacturing a semiconductor memory device, for example, in a step of forming a source line, a gas such as fluorine (F) or hydrogen (H) is sometimes generated in the source line. Such a gas may be diffused to intrude into the portion of a memory cell transistor in which a conductor layer functioning as a word line intersects a memory pillar. In such a case, the quality and durability of the semiconductor memory device sometimes deteriorate.

According to the second modification, the semiconductor memory device 1 includes the block film BF between the conductor portion 30B and the insulator portion EM. This prevents the above gas from reaching a portion of the memory cell transistor MT through the insulator portion EM. It is, therefore, possible to prevent a deterioration in the reliability of the semiconductor memory device 1.

### 2.3 Third Modification

The above embodiment has exemplified the case where the conductor portion 30B extends through the two conductor layers 31. However, the present invention is not limited to this. The conductor portion 30B may extend through only one of the two conductor layers 31. The arrangement of the semiconductor memory device according to the third modification will be described, focusing on differences from the arrangement of the semiconductor memory device according to the embodiment.

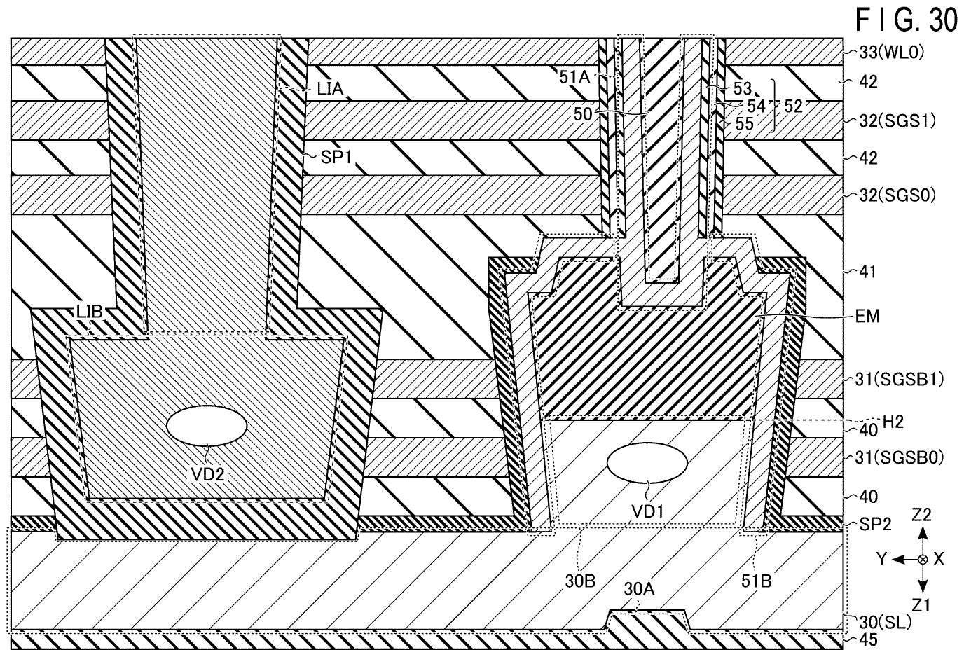

The sectional structure of the memory cell array 10 of the semiconductor memory device 1 according to the third modification will be described with reference to FIG. 30. FIG. 30 is a sectional view showing an example of the sectional structure of the memory cell array of the semiconductor memory device according to the third modification. FIG. 30 corresponds to FIG. 7 in the embodiment.

The second surface of the conductor portion 30B is located on one side relative to the second surface of the conductor layer 31 of the two conductor layers 31 which is located on the other side. The second surface of the conductor portion 30B is located at a height H2 between the two conductor layers 31. That is, the conductor portion 30B extends through the conductor layer 31 on one side but does not extend through the conductor layer 31 on the other side. With the arrangement of the conductor portion 30B described above, a portion of the memory pillar MP at the same height as the selection gate line SGSB1 includes the insulator portion EM. Note that the third modification exemplifies a case where the second surface of the conductor portion 30B is flat.

A method of manufacturing the semiconductor memory device 1 according to the third modification can be substantially similar to the method of manufacturing the semiconductor memory device according to the embodiment.

The third modification can also obtain effects similar to those of the embodiment.

In addition, like the second modification, the third modification can prevent a deterioration in the reliability of the semiconductor memory device 1. Furthermore, in the third modification, providing the conductor portion 30B so as to make it extend through only the conductor layer 31 of the two conductor layers 31 which is located on one side can keep the second surface of the conductor portion 30B away from a portion of the memory cell transistor MT. This makes it possible to reduce the possibility of causing a gas generated, if ever, in the manufacturing step described above to reach a portion of the memory cell transistor MT through the insulator portion EM.

### 2.4 Fourth Modification

Each NAND string NS may include a dummy transistor. The arrangement of a semiconductor memory device according to the fourth modification will be described below, focusing on differences from the arrangement of the semiconductor memory device according to the embodiment.

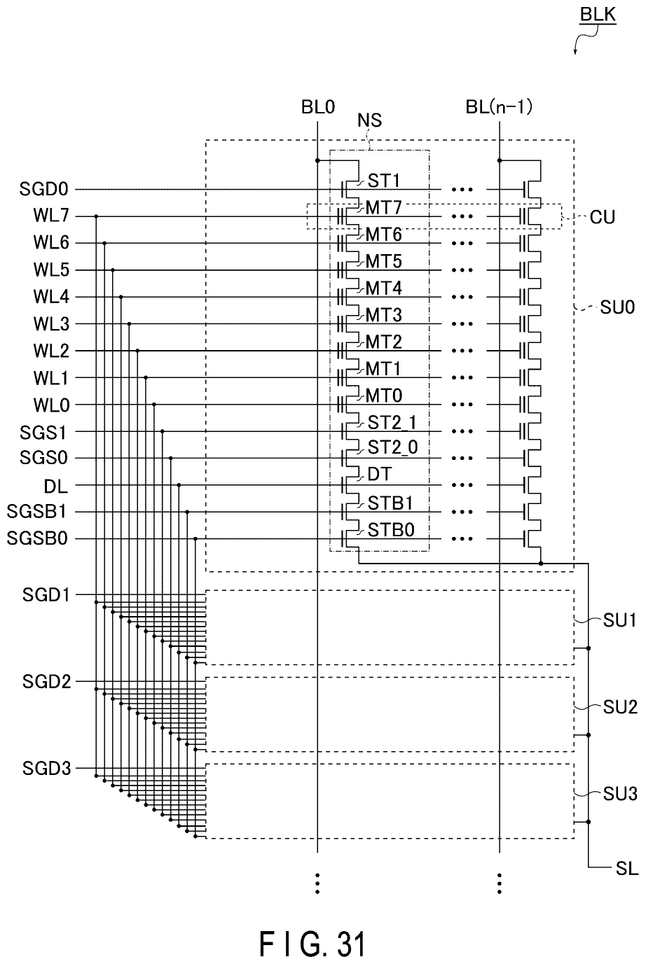

The circuit arrangement of the memory cell array 10 of the semiconductor memory device 1 according to the fourth modification will be described with reference to FIG. 31. FIG. 31 is a circuit diagram showing an example of the circuit arrangement of the memory cell array of the semiconductor memory device according to the fourth modification.

Each NAND string NS further includes, for example, a dummy transistor DT. The dummy transistor DT is a transistor that can have a structure similar to that of the memory cell transistor MT but is not used to store data. Alternatively, the dummy transistor DT may be, for example, a dummy selection transistor that can have a function similar to that of the selection transistor ST2 but is not used to select the block BLK. Although the modification exemplifies a case where each NAND string NS includes one dummy transistor DT, the present invention is not limited to this. Each NAND string NS may include two or more dummy transistors DT.

In each NAND string NS, one terminal of the dummy transistor DT is coupled to the other terminal of the selection transistor ST2 coupled in series. The other terminal of the dummy transistor DT is coupled to one terminal of the selection transistor STB coupled in series. If each NAND string NS includes the two or more dummy transistors DT, the dummy transistors DT are coupled in series between the other terminal of the selection transistor ST2 coupled in series and one terminal of the selection transistor STB coupled in series.

The gate of the dummy transistor DT is coupled to a dummy interconnect DL. In each block BLK, the gates of the plurality of dummy transistors DT are commonly coupled to the dummy interconnect DL. However, the present invention is not limited to this. The gates of the plurality of dummy transistors DT may be respectively coupled to the plurality of dummy interconnects DL that differ for each string unit SU.

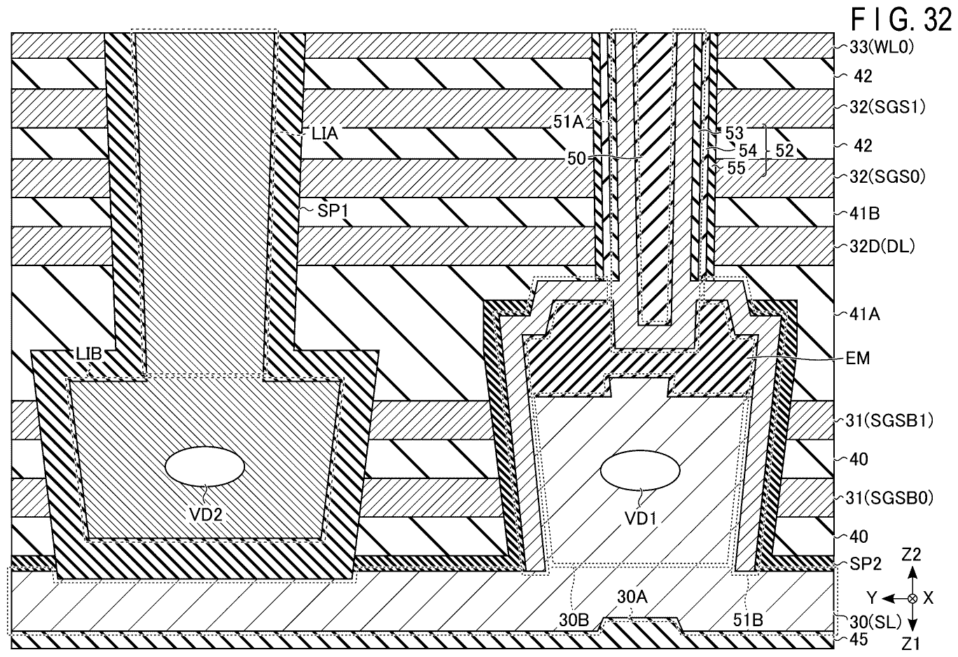

The sectional structure of the memory cell array 10 of the semiconductor memory device 1 according to the fourth modification will be described next with reference to FIG. 32. FIG. 32 is a sectional view showing an example of the sectional structure of the memory cell array of the semiconductor memory device according to the fourth modification. FIG. 32 corresponds to FIG. 7 in the embodiment.

The memory cell array 10 includes insulator layers 41A and 41B instead of the insulator layer 41. The memory cell array 10 further includes a conductor layer 32D.

The insulator layer 41A is stacked on the second surface of the conductor layer 31.

A conductor layer 32D is stacked on the second surface of the insulator layer 41A. The conductor layer 32D is formed, for example, in a plate form expanding along an XY plane. The conductor layer 32D is used as the dummy interconnect DL. The conductor layer 32D contains, for example, tungsten or molybdenum.

The insulator layer 41B is stacked on the second surface of the conductor layer 32D. The second surface of the insulator layer 41B is in contact with the conductor layer 32.

The conductor layer 32D is located on the other side relative to the first surface of the stacked film 52. This makes the second surface of the conductor layer 32D be located on the other side relative to the semiconductor portion 51B. In this case, the dummy transistor DT is formed in the portion where each of the plurality of memory pillars MP intersects the conductor layer 32D. Although not shown, the conductor layer 32D may have, for example, a portion included in the same layer as the insulator portion EM or may be located on one side relative to the second surface of the conductor portion 30B.

A method of manufacturing the semiconductor memory device 1 according to the fourth modification is substantially the same as the method of manufacturing the semiconductor memory device according to the embodiment except that the conductor layer 32D is formed in the same manner as the conductor layers 31 to 34.

The fourth modification can also obtain effects similar to those of the embodiment.

### 3 Others

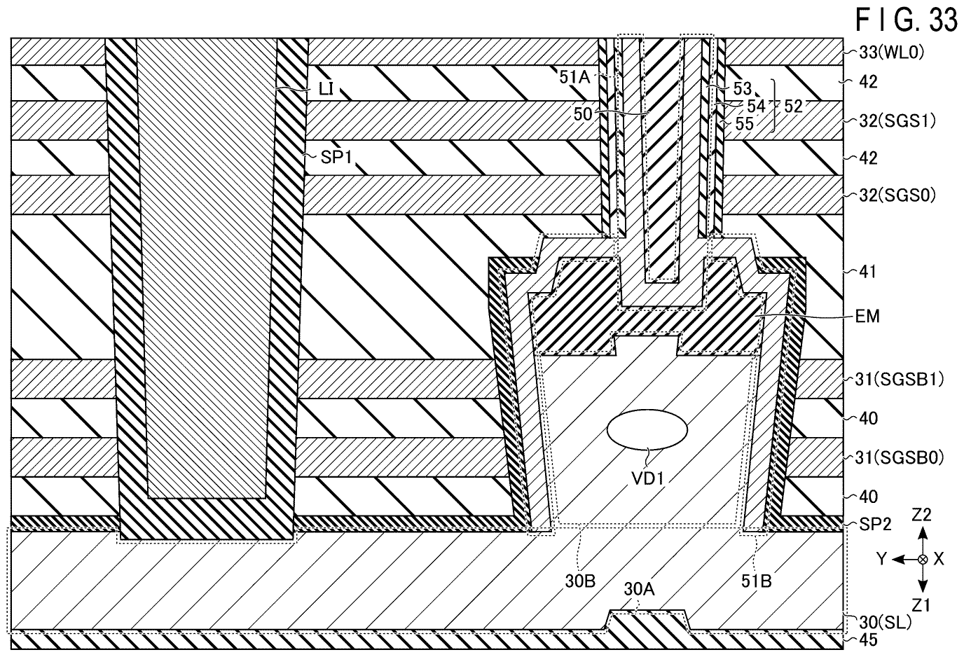

The embodiment and the modifications described above have exemplified the case where the core portion LI includes the stepped portion due to the core portions LIA and LIB. However, the present invention is not limited to this. As shown in FIG. 33, the core portion LI may not have any stepped portion. FIG. 33 is a sectional view showing an example of the sectional structure of the memory cell array of the semiconductor memory device according to another example.

In the semiconductor memory device 1 according to another example, the member SLT and the core portion LI have no stepped portion. The member SLT and the core portion LI are provided so as to, for example, have a bowing shape or increase in width in the X direction or the Y direction toward the Z2 direction.

A method of manufacturing the semiconductor memory device 1 according to another example can be substantially the same as the method of manufacturing the semiconductor memory device according to the embodiment except that the plurality of stopper layers 81 and the plurality of insulator layers 91 which correspond to the core portion LIB are not formed in the step described with reference to FIG. 13 in the embodiment.

The embodiment, the modifications, and another example described above have exemplified the case where the memory chip 1-2 includes one stacked interconnect structure including the conductor layers 31 to 34. However, the present invention is not limited to this. The memory chip 1-2 according to still another example may include a plurality of stacked interconnect structures.

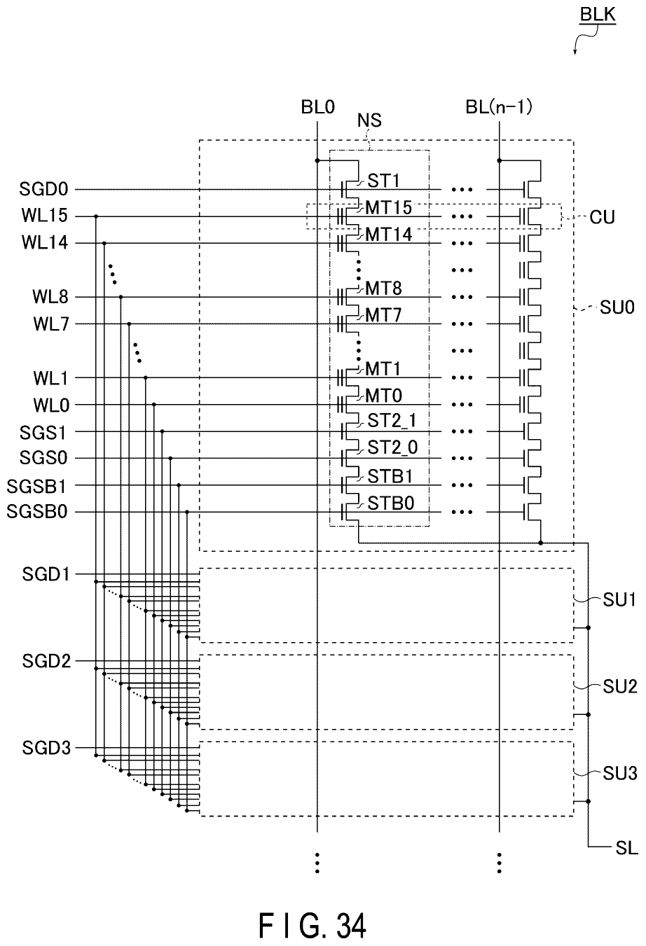

The circuit arrangement of the memory cell array 10 of the semiconductor memory device 1 according to still another example will be described with reference to FIG. 34. FIG. 34 is a circuit diagram showing an example of the circuit arrangement of the memory cell array of the semiconductor memory device according to still another example. The circuit arrangement of the memory cell array 10 of the semiconductor memory device 1 according to still another example is the same as the circuit arrangement of the memory cell array of the semiconductor memory device according to the embodiment except for the number of memory cell transistors MT included in the NAND string NS. In still another example, the NAND string NS includes 16 memory cell transistors MT. Note that in still another example as well, the semiconductor memory device 1 may include the dummy transistor DT as in the modifications.

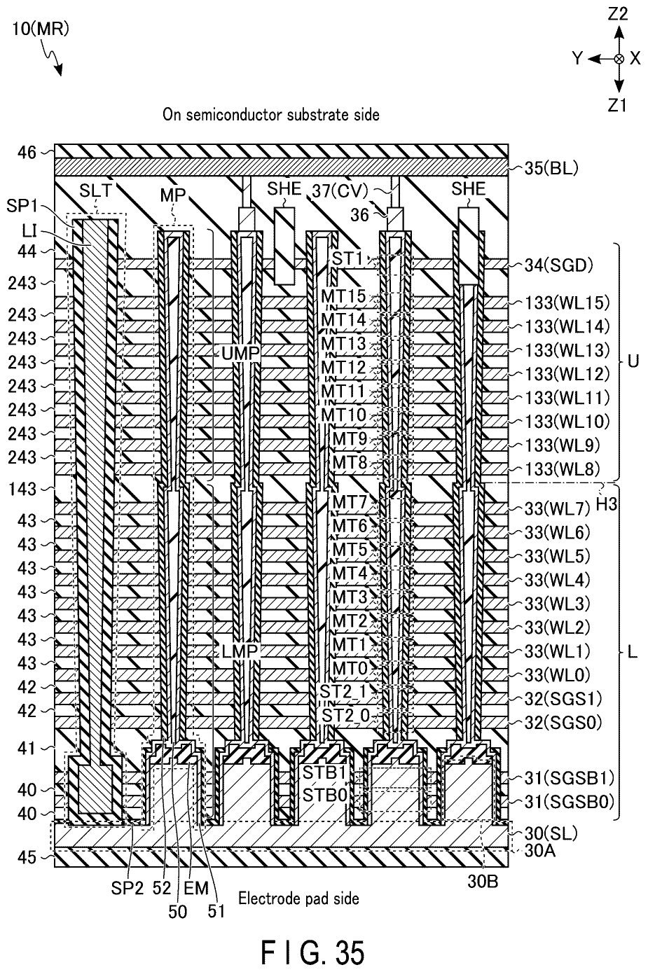

The sectional structure of the memory cell array 10 of the semiconductor memory device 1 according to still another example will be described with reference to FIG. 35. FIG. 35 is a sectional view showing an example of the sectional structure of the memory cell array of the semiconductor memory device according to still another example.

The memory cell array 10 according to still another example further includes a plurality of conductor layers 133, an insulator layer 143, and a plurality of insulator layers 243. Note that in still another example, the number of insulator layers 43 is seven.

In still another example, the insulator layer 143 is stacked on the second surface of the conductor layer 33 located on the other side instead of the insulator layer 43. The eight conductor layers 133 and the eight insulator layers 243 are stacked on the second surface of the insulator layer 143 in the order of the conductor layer 133, the insulator layer 243, . . . , the conductor layer 133, and the insulator layer 243 toward the Z2 direction. The conductor layer 133 is formed in a plate form expanding along an XY plane. The eight conductor layers 133 are sequentially and respectively used as the word lines WL8 to WL15 along the Z2 direction. The conductor layer 133 contains, for example, tungsten or molybdenum.

The conductor layer 34 is stacked on the second surface of the insulator layer 243 of the eight insulator layers 243 which is located on the other side in the Z direction.

In the above arrangement, the structure including the conductor layer 31 corresponding to the selection gate line SGSB, the conductor layer 32 corresponding to the selection gate line SGS, and the plurality of conductor layers 33 corresponding to the word lines WL0 to WL7 is also called a lower stacked interconnect structure L. The structure including the plurality of conductor layers 133 corresponding to the word lines WL8 to WL15 and the conductor layer 34 corresponding to the selection gate line SGD is also called an upper stacked interconnect structure U.

The plurality of memory pillars MP extend through the conductor layers 31 to 33, 133, and 34 on one side relative to the conductor layer 35.

The portion of each memory pillar MP which is located on one side relative to a height H3 of a chain line between the upper stacked interconnect structure U and the lower stacked interconnect structure L is also called a lower memory pillar LMP. The portion of each memory pillar MP which is located on the other side relative to the height H3 is also called an upper memory pillar UMP.

The upper memory pillar UMP and the lower memory pillar LMP each are provided so as to increase in sectional area along XY plane toward the Z2 direction due to the fact that the respective memory holes corresponding to these memory pillars are formed in different steps in the manufacturing process.

The member SLT divides the conductor layers 31 to 33, 133, and 34. The spacer SP1 separates and insulates between the conductor layers 31 to 33, 133, and 34 and the core portion L1.

The portion where each of the plurality of memory pillars MP and each conductor layer 133 functions as the memory cell transistor MT.

In the manufacturing method according to still another example, in manufacturing a portion of the memory chip 1-2, after the structure corresponding to the plurality of sacrificial layers corresponding to the conductor layers 31 to 33 and the lower memory pillar LMP is formed as a lower stacked body, the structure corresponding to the plurality of sacrificial layers corresponding to the conductor layers 133 and 34 and the upper memory pillar UMP is formed as an upper stacked body on the lower stacked body. Replace processing is then executed to replace the sacrificial layers with the conductor layers 31 to 33, 133, and 34.

Still another example can also obtain effects similar to those of the embodiment.

While certain embodiments have been described, these embodiments have been presented by way of example only and are not intended to limit the scope of the invention. Indeed, these embodiments can be implemented in various other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A semiconductor memory device comprising:
a plurality of word lines provided separately from each other in a first direction intersecting a surface of a substrate;
a first interconnect provided separately from the plurality of word lines in the first direction on one side in the first direction relative to the plurality of word lines;
a source line provided separately from the plurality of word lines and the first interconnect on the one side in the first direction relative to the plurality of word lines; and
a memory pillar provided to extend in the first direction so as to intersect the plurality of word lines and the first interconnect and having one end coupled to the source line,
wherein the source line includes a first source portion included on the one side in the first direction relative to the first interconnect and a second source portion coupled to the first source portion and extending in the first direction so as to intersect the first interconnect in correspondence with the memory pillar on the other side in the first direction relative to the first source portion, and
the memory pillar includes
a core member extending from a position on the other side in the first direction relative to the plurality of word lines to a position on the other side in the first direction relative to the second source portion,
a semiconductor film including a first semiconductor portion provided so as to cover a side surface of the core member and a surface of the core member on the one side in the first direction and a second semiconductor portion that is coupled to the first semiconductor portion and in contact with the second source portion so as to cover a side surface of the second source portion on the one side in the first direction relative to the plurality of word lines, and
a stacked film covering a side surface of the first semiconductor portion.

2. The device according to claim 1, wherein the second semiconductor portion and the second source portion are joined to each other by Schottky junction.

3. The device according to claim 1, wherein the memory pillar further includes an insulating film that covers a side surface of the second semiconductor portion at a portion where at least the memory pillar and the first interconnect intersect and differs in film structure from the stacked film.

4. The device according to claim 1, wherein a central position of the first semiconductor portion is different from a central position of the second semiconductor portion in a plane intersecting the first direction.

5. The device according to claim 1, wherein the first source portion is receding to the other side in the first direction in correspondence with the memory pillar on the one side in the first direction.

6. The device according to claim 1, further comprising a second interconnect provided separately from the first interconnect and the plurality of word lines between the first interconnect and the plurality of word lines in the first direction,
wherein the second source portion is provided on the one side in the first direction relative to the second interconnect.

7. The device according to claim 6, wherein the first interconnect and the second interconnect are configured to be independently potential-controlled.

8. The device according to claim 1, wherein the second source portion has a tapered shape increasing in width from the one side to the other side in the first direction.

9. The device according to claim 1, wherein the memory pillar further includes an insulator portion provided between the second source portion and the first semiconductor portion in the first direction.

10. The device according to claim 9, wherein the insulator portion has a portion receding to the other side in the first direction on the one side in the first direction, and
the second source portion has a portion protruding to the other side in the first direction on the other side in the first direction in correspondence with the receding portion of the insulator portion.

11. The device according to claim 9, further comprising an insulator film provided between the insulator portion and the second source portion in the first direction.

12. The device according to claim 1, wherein a sectional area of the second source portion in a plane including the first interconnect and intersecting the first direction is larger than a sectional area of the memory pillar in a plane including a word line of the plurality of word lines which is located on the one side in the first direction and intersecting the first direction.

13. The device according to claim 1, wherein the first interconnect is provided on the one side in the first direction relative to the substrate.

14. A semiconductor memory device comprising:
a plurality of word lines provided separately from each other in a first direction intersecting a surface of a substrate;
a first interconnect provided separately from the plurality of word lines in the first direction on one side in the first direction relative to the plurality of word lines;
a source line provided separately from the plurality of word lines and the first interconnect on the one side in the first direction relative to the plurality of word lines; and
a memory pillar provided to extend in the first direction so as to intersect the plurality of word lines and the first interconnect and having one end coupled to the source line,
wherein the source line includes a first source portion included on the one side in the first direction relative to the first interconnect and a second source portion coupled to the first source portion and extending in the first direction so as to intersect the first interconnect in correspondence with the memory pillar on the other side in the first direction relative to the first source portion,
the memory pillar includes a core member extending from a position on the other side in the first direction relative to the plurality of word lines to a position on the other side in the first direction relative to the second source portion, a semiconductor film including a first semiconductor portion provided on a side surface of the core member and a second semiconductor portion that is coupled to the first semiconductor portion and in contact with the second source portion at a portion where at least the memory pillar intersects the first interconnect, and a stacked film covering a side surface of the first semiconductor portion, and
a first sectional area of the second source portion in a plane intersecting the first direction is larger than a second sectional area of the memory pillar in a plane including a word line of the plurality of word lines which is located on the one side in the first direction and intersecting the first direction.

15. The device according to claim 14, wherein the memory pillar further includes an insulator portion provided between the core member and the second source portion in the first direction.

16. The device according to claim 15, wherein a third sectional area of the memory pillar in a plane including the insulator portion and intersecting the first direction is larger than the second sectional area.

17. The device according to claim 14, wherein the second semiconductor portion and the second source portion are joined to each other by Schottky junction.

18. The device according to claim 14, wherein the memory pillar further includes an insulating film that covers a side surface of the second semiconductor portion at the portion where at least the memory pillar intersects the first interconnect and differs in film structure from the stacked film.

19. The device according to claim 14, wherein a central position of the first semiconductor portion is different from a central position of the second semiconductor portion in a plane intersecting the first direction.

20. The device according to claim 14, wherein the first interconnect is provided on the one side in the first direction relative to the substrate.
